(19) United States
(12) Patent Application Publication
(10) Pub. No.: US 2026/0227880 A1
(43) Pub. Date: Aug. 6, 2026

(54) ELECTRONIC DEVICE

(71) Applicant: Samsung Display Co., Ltd., Yongin-si (KR)

(72) Inventors: KYOWON KU, Yongin-si (KR); HYUNGBAE KIM, Yongin-si (KR); SANGHYUN LIM, Yongin-si (KR)

(21) Appl. No.: 19/378,183

(22) Filed: Nov. 3, 2025

(30) Foreign Application Priority Data
Jan. 31, 2025 (KR) 10-2025-0012741

(51) Int. Cl. G06F 3/044; G06F 3/041

(52) U.S. Cl. CPC G06F 3/0446; G06F 3/0412; G06F 3/04164; G06F 2203/04102; G06F 2203/04111

(57) ABSTRACT

An electronic device includes a display layer including a display area for displaying an image, and a non-display area adjacent to the display area, and a sensor layer above the display layer for sensing an external input, and including first electrodes arranged in a first direction, second electrodes arranged in a second direction crossing the first direction, first charging electrodes arranged in the first direction, second charging electrodes arranged in the first direction, a first loop trace line electrically connected to the first charging electrodes, and a second loop trace line electrically connected to the second charging electrodes, wherein at least one of the first charging electrodes is between at least one of the second charging electrodes and a remainder of the second charging electrodes.

### CROSS-REFERENCE TO RELATED APPLICATION

The present application claims priority to, and the benefit of, Korean Patent Application No. 10-2025-0012741, filed on January 31, 2025, in the Korean Intellectual Property Office, the entire disclosure of which is incorporated herein by reference.

### BACKGROUND

### Field

The present disclosure relates to an electronic device with improved touch performance.

### Description of Related Art

Multimedia electronic devices, such as televisions, mobile phones, tablet computers, notebook computers, navigation units, and game units, include a display device to display images. The electronic devices include a sensor layer (or an input sensor) that provides a touch-based input method allowing users to suitably and intuitively input information or commands in addition to conventional input methods, such as a button, a keyboard, a mouse, etc. The sensor layer senses a touch or pressure generated by a user. Meanwhile, there is a growing demand for the use of pens for users who are accustomed to inputting information using writing tools or for corresponding applications (e.g., applications for sketching or drawing) that require precise touch input.

### SUMMARY

The present disclosure provides an electronic device with improved touch performance.

Embodiments of the present disclosure provide an electronic device including a display layer including a display area for displaying an image, and a non-display area adjacent to the display area, and a sensor layer above the display layer for sensing an external input, and including first electrodes arranged in a first direction, second electrodes arranged in a second direction crossing the first direction, first charging electrodes arranged in the first direction, second charging electrodes arranged in the first direction, a first loop trace line electrically connected to the first charging electrodes, and a second loop trace line electrically connected to the second charging electrodes, wherein at least one of the first charging electrodes is between at least one of the second charging electrodes and a remainder of the second charging electrodes.

The electronic device may further include a sensor driver configured to drive the sensor layer and electrically connected to the first charging electrodes and to the second charging electrodes.

The electronic device may further include a first sensor driver electrically connected to the first charging electrodes, and a second sensor driver electrically connected to the second charging electrodes, which are configured to drive the sensor layer.

The first charging electrodes may be electrically insulated from the second charging electrodes.

The electronic device may further include a sensor driver configured to drive the sensor layer, wherein the sensor layer is configured to selectively operate in a first mode for sensing a touch input, or in a second mode for sensing a pen input and including a charge-driving mode, and wherein the sensor driver is configured to apply a signal to at least a portion of the first charging electrodes to form a first loop in the charge-driving mode, and is configured to apply a signal to at least a portion of the second charging electrodes to form a second loop in the charge-driving mode.

The sensor driver may be configured to drive the first charging electrodes and the second charging electrodes substantially simultaneously in the charge-driving mode.

The first loop trace line may be insulated from the second loop trace line while crossing with the second loop trace line.

The sensor layer may further include third charging electrodes arranged in the first direction, and a third loop trace line electrically connected to the third charging electrodes, wherein at least one of the third charging electrodes is arranged between at least one of the second charging electrodes and a remainder of the second charging electrodes.

The first loop trace line may be insulated from the second loop trace line while crossing with the second loop trace line, wherein the second loop trace line is insulated from the third loop trace line while crossing with the third loop trace line.

The sensor layer may further include first trace lines electrically connected to the first electrodes in a one-to-one correspondence, and second trace lines electrically connected to the second electrodes in a one-to-one correspondence.

The sensor layer may further include auxiliary electrodes arranged in the second direction, and an auxiliary trace line electrically connected to the auxiliary electrodes.

Embodiments of the present disclosure provide an electronic device including a display layer including a display area for displaying an image, and a non-display area adjacent to the display area, a display driver for driving the display layer, a sensor driver, a processor for controlling an operation of the display driver and the sensor driver, and a sensor layer above the display layer, configured to be driven by the sensor driver, configured to selectively operate in a first mode for sensing a touch input, or a second mode for sensing a pen input and including a charge-driving mode, and including first electrodes arranged in a first direction, second electrodes arranged in a second direction crossing the first direction, first charging electrodes arranged in the first direction, second charging electrodes arranged in the first direction and electrically insulated from the first charging electrodes, a first loop trace line electrically connected to the first charging electrodes, and a second loop trace line electrically connected to the second charging electrodes, and wherein the sensor driver is configured to apply a signal to at least a portion of the first charging electrodes to form a first loop in the charge-driving mode, and is configured to apply a signal to at least a portion of the second charging electrodes to form a second loop in the charge-driving mode.

The sensor driver may be electrically connected to the first charging electrodes and to the second charging electrodes.

The sensor driver may further include a first sensor driver electrically connected to the first charging electrodes, and a second sensor driver electrically connected to the second charging electrodes.

The sensor driver may be configured to substantially simultaneously drive the first charging electrodes and the second charging electrodes in the charge-driving mode.

The sensor driver may be configured to drive either the first charging electrodes or the second charging electrodes in the charge-driving mode.

The first loop trace line may be insulated from the second loop trace line while crossing with the second loop trace line.

At least one of the first charging electrodes may be between at least one of the second charging electrodes and a remainder of the second charging electrodes.

The sensor layer may further include third charging electrodes arranged in the first direction, and a third loop trace line electrically connected to the third charging electrodes, wherein at least one of the third charging electrodes is arranged between at least one of the second charging electrodes and a remainder of the second charging electrodes.

The first loop trace line may be insulated from the second loop trace line while crossing with the second loop trace line, wherein the second loop trace line is insulated from the third loop trace line while crossing with the third loop trace line.

According to the above, a portion of the first charging electrodes and a portion of the second charging electrodes are arranged to cross with each other. Consequently, a current loop that generates a magnetic field to charge the pen is formed across the entire area of the sensor layer. In addition, a current loop using the first charging electrodes and a current loop using the second charging electrodes are formed concurrently or substantially simultaneously. As a pen-charging performance (e.g., a pen-charging speed and/or a pen-charging rate) is improved, the linearity and accuracy of a pen input is also enhanced, and a time required to scan the entire area of the sensor layer is reduced by more than half. In other words, the touch performance of the electronic device is improved.

### BRIEF DESCRIPTION OF THE DRAWINGS

FIG. 1 is a block diagram of an electronic device according to one or more embodiments of the present disclosure;

FIG. 2A is a perspective view of an electronic device according to one or more embodiments of the present disclosure;

FIG. 2B is a rear perspective view of an electronic device according to one or more embodiments of the present disclosure;

FIG. 3 is a perspective view of an electronic device according to one or more embodiments of the present disclosure;

FIG. 4 is a perspective view of an electronic device according to one or more embodiments of the present disclosure;

FIG. 5 is a cross-sectional view of a display panel according to one or more embodiments of the present disclosure;

FIG. 6 is a view illustrating an operation of an electronic device according to one or more embodiments of the present disclosure;

FIG. 7A is a cross-sectional view of a display panel according to one or more embodiments of the present disclosure;

FIG. 7B is a cross-sectional view of some components of a sensor layer according to one or more embodiments of the present disclosure;

FIG. 8 is a plan view of a sensor layer according to one or more embodiments of the present disclosure;

FIG. 9A is a plan view of a first conductive layer of a sensing unit according to one or more embodiments of the present disclosure;

FIG. 9B is a plan view of a second conductive layer of a sensing unit according to one or more embodiments of the present disclosure;

FIG. 10 is an enlarged plan view of an area AA’ shown in FIG. 9B;

FIG. 11 is a view illustrating an operation of a sensor driver according to one or more embodiments of the present disclosure;

FIG. 12 is a view illustrating an operation of a sensor driver according to one or more embodiments of the present disclosure;

FIG. 13 is a view illustrating a first mode according to one or more embodiments of the present disclosure;

FIG. 14 is a view illustrating a second mode (a charge-driving mode) according to one or more embodiments of the present disclosure;

FIG. 15A is a graph illustrating a waveform of a first signal and a first-first signal according to one or more embodiments of the present disclosure;

FIG. 15B is a graph illustrating a waveform of a second signal and a second-first signal according to one or more embodiments of the present disclosure;

FIG. 16 is a view illustrating a second mode (a charge-driving mode) according to one or more embodiments of the present disclosure;

FIG. 17A is a view illustrating a first signal and a second signal according to one or more embodiments of the present disclosure;

FIG. 17B is a view illustrating a first signal and a second signal according to one or more embodiments of the present disclosure;

FIG. 18 is a view illustrating a first sensor driver and a second sensor driver according to one or more embodiments of the present disclosure;

FIG. 19 is a view illustrating an electronic device including a sensor layer according to one or more embodiments of the present disclosure;

FIG. 20A is a view illustrating a second mode according to one or more embodiments of the present disclosure; and

FIG. 20B is a view illustrating a second mode with respect to one sensing unit according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

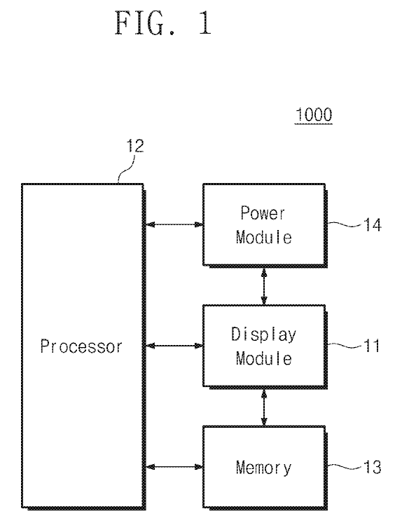

FIG. 1 is a block diagram of an electronic device 1000 according to one or more embodiments of the present disclosure.

Referring to FIG. 1, the electronic device 1000 may include a display module 11, a processor 12, a memory 13, and a power module 14.

The display module 11 may display an image. The image may include a still image as well as a video. The processor 12 may include at least one of a central processing unit (CPU), an application processor (AP), a graphics processing unit (GPU), a communication processor (CP), an image signal processor (ISP), or a controller. The processor 12 may control an operation of the display module 11.

The memory 13 may store data information required for the operation of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module, such as a power adapter or a battery device, and a power conversion module that converts power supplied by the power supply module to generate power required for the operation of the electronic device 1000.

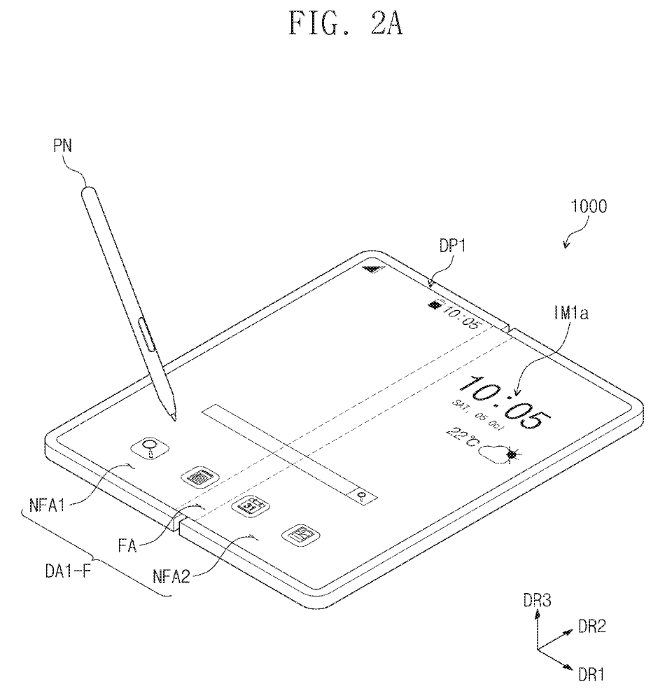

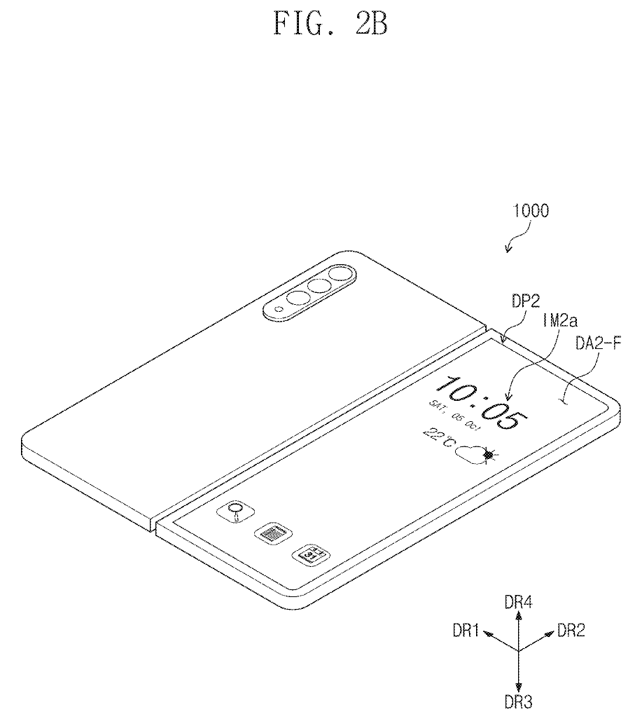

FIG. 2A is a perspective view of the electronic device 1000 according to one or more embodiments of the present disclosure. FIG. 2B is a rear perspective view of the electronic device 1000 according to one or more embodiments of the present disclosure.

Referring to FIGS. 2A and 2B, the electronic device 1000 may be activated in response to electrical signals. As an example, the electronic device 1000 may display images and may sense inputs applied from the outside. The external input may be a user input. The user input may include a variety of forms of external inputs, such as a part of user’s body, pen PN, light, heat, or pressure.

The electronic device 1000 may include a first display panel DP1 and a second display panel DP2. The first display panel DP1 and the second display panel DP2 may be panels separated from each other. The first display panel DP1 may be referred to as a main display panel, and the second display panel DP2 may be referred to as an auxiliary display panel or an external display panel.

The first display panel DP1 may include a first display part DA1-F, and the second display panel DP2 may include a second display part DA2-F. The second display panel DP2 may have a size that is smaller than a size of the first display panel DP1. Accordingly, corresponding to the sizes of the first display panel DP1 and the second display panel DP2, the first display part DA1-F may have a size that is greater than a size of the second display part DA2-F.

When the electronic device 1000 is in an unfolded state, the first display part DA1-F may include a plane substantially parallel to each of a first direction DR1 and a second direction DR2. A thickness direction of the electronic device 1000 may be substantially parallel to a third direction DR3 crossing the first direction DR1 and the second direction DR2. Hereinafter, front (or upper) and rear (or lower) surfaces of each member of the electronic device 1000 may be defined based on the third direction DR3.

The first display panel DP1 or the first display part DA1-F may include a folding area FA that is folded or unfolded and a plurality of non-folding areas NFA1 and NFA2 spaced apart from each other to allow the folding area FA to be located between the non-folding areas NFA1 and NFA2. The second display panel DP2 may overlap one of the non-folding areas NFA1 and NFA2. As an example, the second display panel DP2 may overlap a first non-folding area NFA1.

A display direction of a first image IM1a displayed through the first display panel DP1 may be opposite to a display direction of a second image IM2a displayed through the second display panel DP2. As an example, the first image IM1a may be displayed to the third direction DR3, and the second image IM2a may be displayed to a fourth direction DR4 opposite to the third direction DR3.

The folding area FA may be folded with respect to a folding axis that extends in a direction parallel to long sides of the electronic device 1000 (e.g., a direction that is parallel to the second direction DR2). When the electronic device 1000 is in a folded state, the folding area FA may have a curvature and a radius of curvature. The electronic device 1000 may be inwardly folded (inner-folding) such that the first non-folding area NFA1 faces a second non-folding area NFA2 and the first display part DA1-F is not exposed to the outside.

According to one or more embodiments, the electronic device 1000 may be outwardly folded (outer-folding) such that the first display part DA1-F is exposed to the outside. According to one or more embodiments, the electronic device 1000 may be inwardly folded or outwardly folded from the unfolded state, although it should not be limited thereto or thereby.

FIG. 2A shows the structure in which the electronic device 1000 includes one folding area FA defined therein as a representative example, although the present disclosure should not be limited thereto or thereby. As an example, a plurality of folding axes and a plurality of folding areas corresponding to the folding axes may be defined in the electronic device 1000, and the electronic device 1000 may be inwardly or outwardly folded from the unfolded state in each of the folding areas.

According to one or more embodiments, at least one of the first display panel DP1 or the second display panel DP2 may sense an input from the pen PN without including a digitizer. Because the digitizer for sensing the input by the pen PN is omitted, an increase in thickness and weight and a decrease in flexibility of the electronic device 1000 due to the addition of the digitizer may be reduced or prevented. In addition, the other of the first display panel DP1 and the second display panel DP2 may also be designed to sense the pen PN.

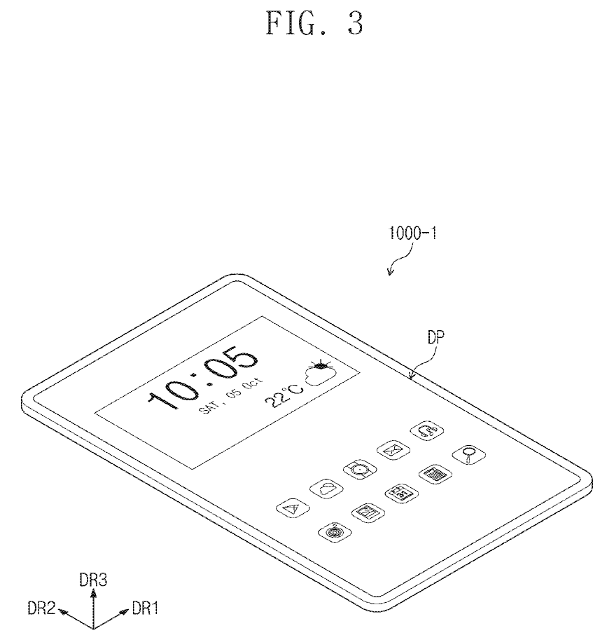

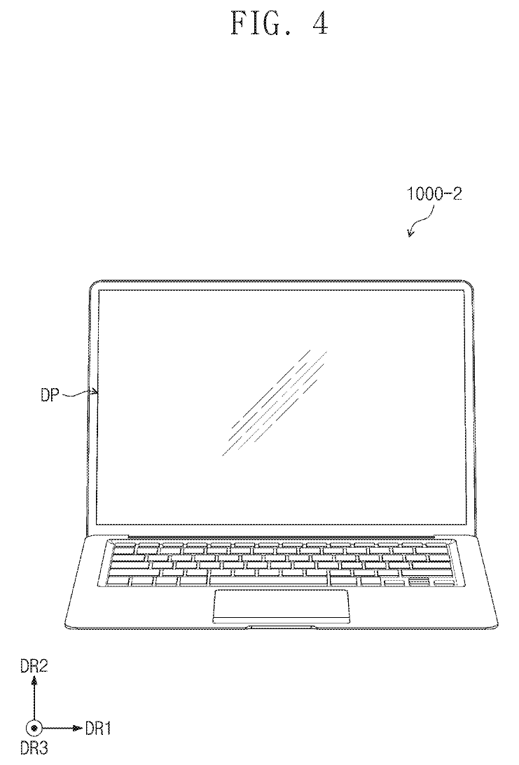

FIG. 3 is a perspective view of an electronic device 1000-1 according to one or more embodiments of the present disclosure. FIG. 4 is a perspective view of an electronic device 1000-2 according to one or more embodiments of the present disclosure.

FIG. 3 shows a bar-type mobile phone as a representative example of the electronic device 1000-1, and the electronic device 1000-1 may include a display panel DP. FIG. 4 shows a notebook computer as a representative example of the electronic device 1000-2, and the electronic device 1000-2 may include a display panel DP. FIG. 4 is a perspective view of the electronic device 1000-2, but coordinate axes shown in FIG. 4 are illustrated based on the display panel DP within the electronic device 1000-2.

The display panel DP may sense external inputs applied from the outside. The external input may be a user input. The user input may include a variety of forms of external inputs, such as a part of a user’s body, pen (refer to PN of FIG. 1A), light, heat, or pressure.

According to one or more embodiments the display panel DP may sense an input given thereto by the pen PN even without including a digitizer. Because the digitizer to sense the input by the pen PN is omitted, an increase in thickness and weight of the electronic device 1000-1 or 1000-2 due to the addition of the digitizer may be reduced or prevented.

FIG. 2A shows a foldable-type electronic device 1000, and FIG. 3 shows a bar-type electronic device 1000-1. However, the present disclosure should not be limited thereto or thereby. As an example, the following descriptions may be applied to various electronic devices, such as a rollable type electronic device, a slidable type electronic device, a stretchable type electronic device, etc.

FIG. 5 is a cross-sectional view schematically showing the display panel DP according to one or more embodiments of the present disclosure.

Referring to FIG. 5, the display panel DP may include a display layer 100 and a sensor layer 200. An upper functional member may further be located on the sensor layer 200. As an example, the upper functional member may include at least one of an anti-reflective layer, a window, or a protective film.

The display layer 100 may have a configuration that substantially generates the image. The display layer 100 may include a display area 100A, and a non-display area 100NA adjacent to the display area 100A, which are defined therein. The image may be displayed through the display area 100A.

The display layer 100 may be a light-emitting type display layer. For example, the display layer 100 may be an organic light-emitting display layer, an inorganic light-emitting display layer, an organic-inorganic light-emitting display layer, a quantum dot display layer, a micro-LED display layer, or a nano-LED display layer. The display layer 100 may include a base layer 110, a circuit layer 120, a light-emitting element layer 130, and an encapsulation layer 140.

The base layer 110 may provide a base surface on which the circuit layer 120 is located. The base layer 110 may have a single-layer or multi-layer structure. The base layer 110 may be a glass substrate, a metal substrate, a silicon substrate, or a polymer substrate, although the present disclosure should not be particularly limited.

The circuit layer 120 may be located on the base layer 110. The circuit layer 120 may include an insulating layer, a semiconductor pattern, a conductive pattern, and a signal line. An insulating layer, a semiconductor layer, and a conductive layer may be formed on the base layer 110 by a coating or depositing process. Then, the insulating layer, the semiconductor layer, and the conductive layer may be selectively patterned through several photolithography processes.

The light-emitting element layer 130 may be located on the circuit layer 120. The light-emitting element layer 130 may include a light-emitting element. For example, the light-emitting element layer 130 may include an organic light-emitting material, an inorganic light-emitting material, an organic-inorganic light-emitting material, a quantum dot, a quantum rod, a micro-LED, or a nano-LED.

The encapsulation layer 140 may be located on the light-emitting element layer 130. The encapsulation layer 140 may protect the light-emitting element layer 130 from moisture, oxygen, and foreign substances, such as dust particles.

The sensor layer 200 may be located on the display layer 100. The sensor layer 200 may include a sensing area 200A and a peripheral area 200NA adjacent to the sensing area 200A, which are defined therein. The sensing area 200A may overlap the display area 100A, and the peripheral area 200NA may overlap the non-display area 100NA.

According to one or more embodiments, the sensing area 200A may have a size greater than or equal to a size of the display area 100A. FIG. 5 shows the structure in which the size of the sensing area 200A is equal to the size of the display area 100A as a representative example, although the present disclosure should not be limited thereto or thereby. As an example, a portion of the sensing area 200A may overlap the non-display area 100NA, and the size of the sensing area 200A may be greater than the size of the display area 100A. In this case, even when the input occurs adjacent to a boundary between the display area 100A and the non-display area 100NA, the input may be sufficiently sensed because the sensing area 200A overlaps a portion of the non-display area 100NA. Accordingly, the coordinate accuracy for touches entered at the periphery of the display area 100A may be further improved.

The sensor layer 200 may sense the external input applied from the outside. The sensor layer 200 may be an integrated sensor formed continuously in a manufacturing process of the display layer 100, or the sensor layer 200 may be an external type sensor attached to the display layer 100. The sensor layer 200 may be referred to as a sensor, an input-sensing layer, an input-sensing panel, or an electronic device for sensing input coordinate.

According to one or more embodiments, the sensor layer 200 may sense both inputs from a passive type input member such as a part of a user’s body and inputs from an input device that generates a magnetic field with a selected resonant frequency. The input device may be referred to as a pen, an input pen, a magnetic pen, a stylus pen, or an electromagnetic resonance pen.

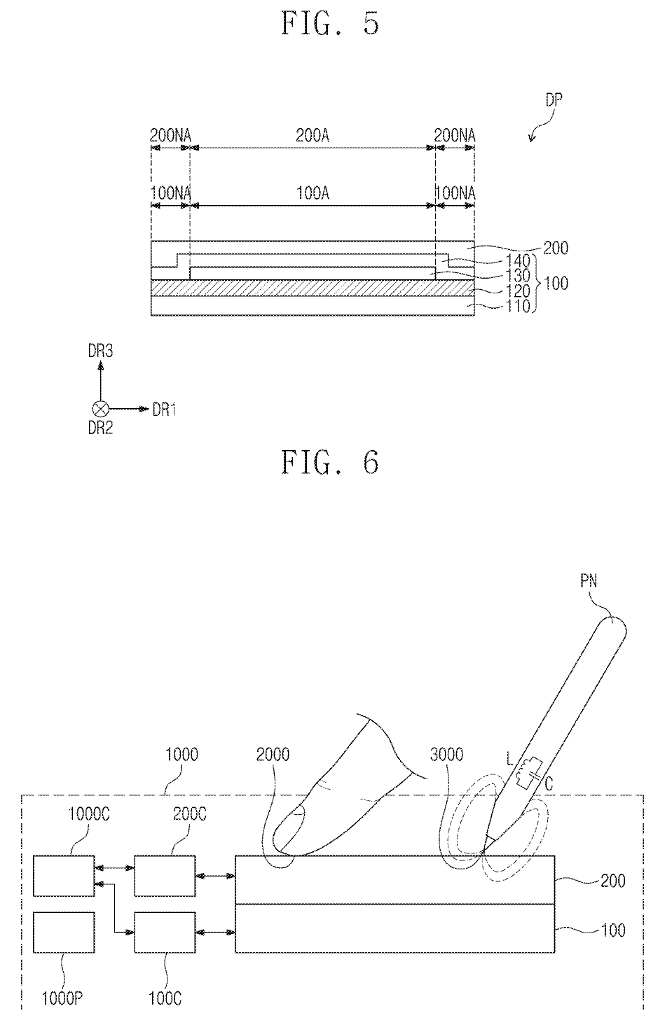

FIG. 6 is a view illustrating an operation of the electronic device 1000 according to one or more embodiments of the present disclosure.

Referring to FIG. 6, the electronic device 1000 may include the display layer 100, the sensor layer 200, a display driver 100C, a sensor driver 200C, a main driver 1000C, and a power circuit 1000P.

The sensor layer 200 may sense a first input 2000 or a second input 3000 that is applied from the outside. Each of the first input 2000 and the second input 3000 may be an input by an input member that causes a variation in capacitance of the sensor layer 200 or an input by an input member that induces current in the sensor layer 200. As an example, the first input 2000 may be an input by a passive- type input member such as a part of a user’s body. The second input 3000 may be an input generated by the pen PN or an input by an RFIC (Radio Frequency Integrated Circuit) tag. As an example, the pen PN may be a passive-type pen or an active-type pen.

The pen PN may be a device that generates a magnetic field of a selected resonant frequency. The pen PN may be configured to transmit an output signal based on an electromagnetic resonance method. The pen PN may be referred to as an input device, an input pen, a magnetic pen, a stylus pen, or an electromagnetic resonance pen.

The pen PN may include an RLC resonant circuit, and the RLC resonant circuit may include an inductor L and a capacitor C. The RLC resonant circuit may be a variable resonant circuit that varies a resonant frequency. In this case, the inductor L may be a variable inductor and/or the capacitor C may be a variable capacitor, although the present disclosure should not be limited thereto or thereby.

The inductor L may generate current by a magnetic field formed in the electronic device 1000 (e.g., the sensor layer 200), although the present disclosure should not be limited thereto or thereby. As an example, when the pen PN operates as an active type, the pen PN may generate current even without receiving a magnetic field from the outside. The generated current may be transmitted to the capacitor C. The capacitor C may be charged with current input from the inductor L and may discharge the charged current to the inductor L. Then, the inductor L may emit the magnetic field at the resonant frequency. The induced current may flow through the sensor layer 200 due to the magnetic field emitted by the pen PN, and the induced current may be transmitted to the sensor driver 200C as a reception signal (or a sensing signal, a signal).

The main driver 1000C may control an overall operation of the electronic device 1000. For example, the main driver 1000C may control an operation of the display driver 100C and the sensor driver 200C. That is, the main driver 1000C may control an operation of the display layer 100 and the sensor layer 200. The main driver 1000C may include at least one microprocessor and may further include a graphics controller. The main driver 1000C may be referred to as an application processor, a central processing unit, or a main processor. The main driver 1000C may correspond to the processor 12 shown in FIG. 1.

The display driver 100C may drive the display layer 100. The display driver 100C may receive image data and a control signal from the main driver 1000C. The control signal may include a variety of signals. As an example, the control signal may include an input vertical synchronization signal, an input horizontal synchronization signal, a main clock signal, a data enable signal, or the like.

The sensor driver 200C may drive the sensor layer 200. The sensor driver 200C may receive a control signal from the main driver 1000C. The control signal may include a clock signal of the sensor driver 200C. In addition, the control signal may further include a mode determination signal that determines a driving mode of the sensor driver 200C and the sensor layer 200.

The sensor driver 200C may be implemented as an integrated circuit (IC) and may be electrically connected to the sensor layer 200. As an example, the sensor driver 200C may be directly mounted on a selected area of the display panel or may be electrically connected to the sensor layer 200 after being mounted on a separated printed circuit board in a chip-on-film (COF) manner.

The sensor driver 200C and the sensor layer 200 may selectively operate in a first mode or a second mode. As an example, the first mode may be a mode to sense a touch input (e.g., the first input 2000). The second mode may be a mode to sense the input generated by the pen PN (e.g., the second input 3000). The first mode may be referred to as a touch sensing mode, and the second mode may be referred to as a pen-sensing mode.

The first mode and the second mode may be switched in a variety of ways. As an example, the sensor driver 200C and the sensor layer 200 may operate in a time-division manner between the first mode and the second mode and may sense the first input 2000 and the second input 3000. In addition, switching between the first mode and the second mode may occur based on a user’s selection or a user’s corresponding action (or input), or one of the first mode and the second mode may be activated or deactivated or a switch from one of the first mode and the second mode to the other may occur based on whether a corresponding application is activated or deactivated. When the first input 2000 is sensed while the sensor driver 200C and the sensor layer 200 are alternately operated in the first mode and the second mode, the first mode may be maintained, and when the second input 3000 is sensed while the sensor driver 200C and the sensor layer 200 are alternately operated in the first mode and the second mode, the second mode may be maintained.

The sensor driver 200C may calculate coordinate information of the input based on the signal applied thereto from the sensor layer 200 and may provide a coordinate signal having the coordinate information to the main driver 1000C. The main driver 1000C may execute an operation corresponding to the user’s input based on the coordinate signal. For instance, the main driver 1000C may drive the display driver 100C so that a new application image is displayed on the display layer 100.

The power circuit 1000P may include a power management integrated circuit (PMIC). The power circuit 1000P may generate a plurality of driving voltages to drive the display layer 100, the sensor layer 200, the display driver 100C, and the sensor driver 200C. As an example, the driving voltages may include a gate high voltage, a gate low voltage, a first driving voltage, a second driving voltage, an initialization voltage, etc., although the present disclosure should not be particularly limited.

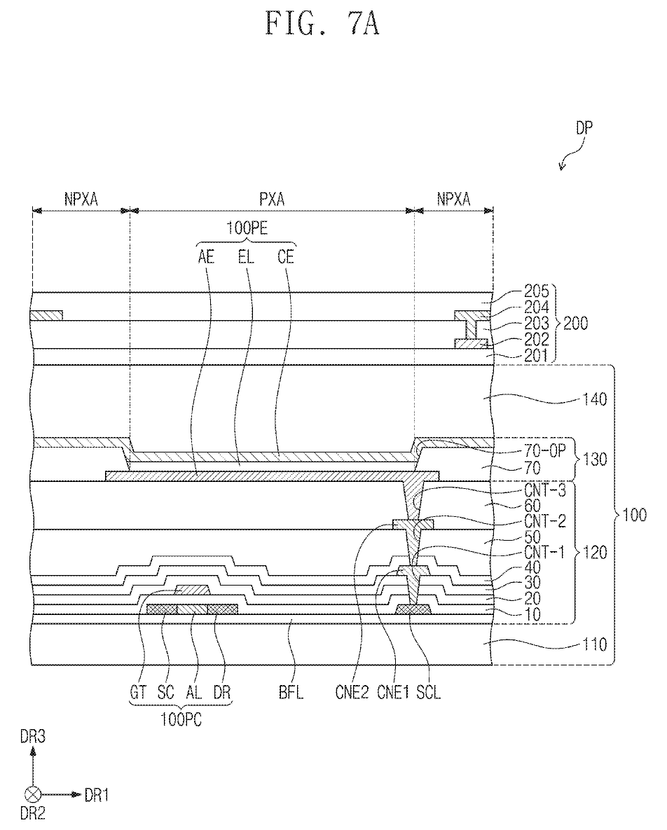

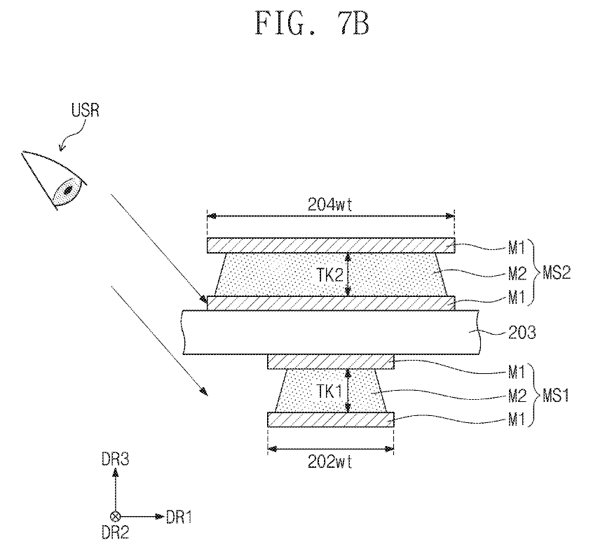

FIG. 7A is a cross-sectional view of the display panel DP according to one or more embodiments of the present disclosure.

Referring to FIG. 7A, at least one buffer layer BFL may be formed on an upper surface of the base layer 110. The buffer layer BFL may increase an adhesive force between the base layer 110 and the semiconductor pattern. The buffer layer BFL may be formed in multiple layers. The display layer 100 may further include a barrier layer. The buffer layer BFL may include at least one of silicon oxide, silicon nitride, or silicon oxynitride. For example, the buffer layer BFL may have a stack structure in which a silicon oxide layer and a silicon nitride layer are alternately stacked with each other.

The semiconductor pattern SC, AL, DR, and SCL may be located on the buffer layer BFL. The semiconductor pattern SC, AL, DR, and SCL may include polysilicon, although it should not be limited thereto or thereby. The semiconductor pattern SC, AL, DR, and SCL may include amorphous silicon, low temperature polycrystalline silicon, or oxide semiconductor.

FIG. 7A shows only a portion of the semiconductor pattern SC, AL, DR, and SCL, and the semiconductor pattern may be further located in other areas. The semiconductor pattern SC, AL, DR, and SCL may be arranged with a corresponding rule over pixels. The semiconductor pattern SC, AL, DR, and SCL may have different electrical properties depending on whether it is doped or not. The semiconductor pattern SC, AL, DR, and SCL may include a first region SC, DR, and SCL having a relatively high conductivity and a second region AL having a relatively low conductivity. The first region SC, DR, and SCL may be doped with an N-type dopant or a P-type dopant. A P-type transistor may include a doped region doped with the P-type dopant, and an N-type transistor may include a doped region doped with the N-type dopant. The second region AL may be a non-doped region or a region doped at a concentration lower than that of the first region SC, DR, and SCL.

The first region SC, DR, and SCL may have a conductivity higher than that of the second region AL and may substantially serve as an electrode or signal line. The second region AL may substantially correspond to an active area AL (or a channel) of a transistor 100PC. In other words, a portion AL of the semiconductor pattern SC, AL, DR, and SCL may be the active area AL of the transistor 100PC, another portion SC or DR of the semiconductor pattern SC, AL, DR, and SCL may be a source area SC or a drain area DR of the transistor 100PC, and the other portion SCL of the semiconductor pattern SC, AL, DR, and SCL may be a connection electrode or a connection signal line SCL.

Each of the pixels may have an equivalent circuit that includes a plurality of transistors, at least one capacitor, and at least one light-emitting element, and the equivalent circuit of the pixel may be modified into various configurations. FIG. 7A shows one transistor 100PC and one light-emitting element 100PE included in the pixel as a representative example.

The source area SC, the active area AL, and the drain area DR of the transistor 100PC may be formed from the semiconductor pattern SC, AL, DR, and SCL. The source area SC and the drain area DR may extend in opposite directions to each other from the active area AL in a cross-section. FIG. 7A shows a portion of the connection signal line SCL formed from the semiconductor pattern SC, AL, DR, and SCL. Although not shown in figures, the connection signal line SCL may be connected to the drain area DR of the transistor 100PC in a plane.

A first insulating layer 10 may be located on the buffer layer BFL (as used herein, “located on” may mean “above”). The first insulating layer 10 may commonly overlap the pixels and may cover the semiconductor pattern SC, AL, DR, and SCL. The first insulating layer 10 may be an inorganic layer and/or an organic layer and may have a single-layer or multi-layer structure. The first insulating layer 10 may include at least one of aluminum oxide, titanium oxide, silicon oxide, silicon nitride,

silicon oxynitride, zirconium oxide, or hafnium oxide. The first insulating layer 10 may have a single-layer structure of a silicon oxide layer. Not only the first insulating layer 10, but also an insulating layer of the circuit layer 120 described later may be an inorganic layer and/or an organic layer and may have a single-layer or multi-layer structure. The inorganic layer may include at least one of the above-mentioned materials, although it should not be limited thereto or thereby.

A gate GT of the transistor 100PC may be located on the first insulating layer 10. The gate GT may be a portion of a metal pattern. The gate GT may overlap the active area AL. The gate GT may be used as a mask in a process of doping or reducing the semiconductor pattern SC, AL, DR, and SCL.

A second insulating layer 20 may be located on the first insulating layer 10 and may cover the gate GT. The second insulating layer 20 may commonly overlap the pixels. The second insulating layer 20 may be an inorganic layer and/or an organic layer and may have a single-layer or multi-layer structure. The second insulating layer 20 may include at least one of silicon oxide, silicon nitride, or silicon oxynitride. The second insulating layer 20 may have a multi-layer structure of a silicon oxide layer and a silicon nitride layer.

A third insulating layer 30 may be located on the second insulating layer 20. The third insulating layer 30 may have a single-layer or multi-layer structure. As an example, the third insulating layer 30 may have a multi-layer structure of a silicon oxide layer and a silicon nitride layer.

A first connection electrode CNE1 may be located on the third insulating layer 30. The first connection electrode CNE1 may be connected to the connection signal line SCL via a contact hole CNT-1 defined through the first, second, and third insulating layers 10, 20, and 30.

A fourth insulating layer 40 may be located on the third insulating layer 30. The fourth insulating layer 40 may have a single-layer structure of a silicon oxide layer. A fifth insulating layer 50 may be located on the fourth insulating layer 40. The fifth insulating layer 50 may be an organic layer.

A second connection electrode CNE2 may be located on the fifth insulating layer 50. The second connection electrode CNE2 may be connected to the first connection electrode CNE1 via a contact hole CNT-2 defined through the fourth insulating layer 40 and the fifth insulating layer 50.

A sixth insulating layer 60 may be located on the fifth insulating layer 50 and may cover the second connection electrode CNE2. The sixth insulating layer 60 may be an organic layer.

The light-emitting element layer 130 may be located on the circuit layer 120. The light-emitting element layer 130 may include the light-emitting element 100PE. As an example, the light-emitting element layer 130 may include an organic light-emitting material, an inorganic light-emitting material, an organic-inorganic light-emitting material, a quantum dot, a quantum rod, a micro-LED, or a nano-LED. Hereinafter, the organic light-emitting element will be described as the light-emitting element 100PE, although it should not be particularly limited.

The light-emitting element 100PE may include a first electrode AE, a light-emitting layer EL, and a second electrode CE. The light-emitting element 100PE may be located in the display area 100A (refer to FIG. 5). The first electrode AE may be referred to as a pixel electrode, and the second electrode CE may be referred to as a common electrode.

The first electrode AE may be located on the sixth insulating layer 60. The first electrode AE may be connected to the second connection electrode CNE2 via a contact hole CNT-3 defined through the sixth insulating layer 60.

A pixel definition layer 70 may be located on the sixth insulating layer 60 and may cover a portion of the first electrode AE. An opening 70-OP may be defined through the pixel definition layer 70. At least a portion of the first electrode AE may be exposed through the opening 70-OP of the pixel definition layer 70.

The display area 100A (refer to FIG. 5) may include a light-emitting area PXA, and a non-light-emitting area NPXA adjacent to the light-emitting area PXA. The non-light-emitting area NPXA may surround the light-emitting area PXA. The light-emitting area PXA may be defined to correspond to the portion of the first electrode AE exposed through the opening 70-OP.

The light-emitting layer EL may be located on the first electrode AE. The light-emitting layer EL may be located in an area corresponding to the opening 70-OP. FIG. 7A shows a structure in which the light-emitting layer EL is located in the opening 70-OP as a representative example, although the present disclosure should not be particularly limited. As an example, the light-emitting layer EL may extend to cover a side surface of the pixel definition layer 70, which defines the opening 70-OP, and a portion of an upper surface of the pixel definition layer 70.

The light-emitting layer EL may be formed in each of the pixels after being divided into plural portions. When the light-emitting layer EL is formed in each of the pixels after being divided into plural portions, each of the light-emitting layers EL may emit a light having at least one of blue, red, or green colors, although it should not be limited thereto or thereby. The light-emitting layer EL may have an integral shape and may be commonly provided to the pixels. In this case, the light-emitting layer EL may provide a blue light or a white light.

The second electrode CE may be located on the light-emitting layer EL. The second electrode CE may have an integral shape and may be commonly located over the pixels.

A hole control layer may be located between the first electrode AE and the light-emitting layer EL. The hole control layer may be commonly located in the light-emitting area PXA and the non-light-emitting area NPXA. The hole control layer may include a hole transport layer and may further include a hole injection layer. An electron control layer may be located between the light-emitting layer EL and the second electrode CE. The electron control layer may include an electron transport layer and may further include an electron injection layer. Each of the hole control layer and the electron control layer may be commonly formed in the plural pixels using an open mask or an inkjet process.

The encapsulation layer 140 may be located on the light-emitting element layer 130. The encapsulation layer 140 may include an inorganic layer, an organic layer, and an inorganic layer, which are sequentially stacked one on another, although the layers of the encapsulation layer 140 should not be limited thereto or thereby. The inorganic layers may protect the light-emitting element layer 130 from moisture and oxygen, and the organic layer may protect the light-emitting element layer 130 from a foreign substance such as dust particles. The inorganic layers may include a silicon nitride layer, a silicon oxynitride layer, a silicon oxide layer, a titanium oxide layer, or an aluminum oxide layer. The organic layer may include an acrylic-based organic layer, although it should not be limited thereto or thereby.

The sensor layer 200 may include a base layer 201, a first conductive layer 202, an intermediate insulating layer 203, a second conductive layer 204, and a cover insulating layer 205.

The base layer 201 may be an inorganic layer including at least one of silicon nitride, silicon oxynitride, or silicon oxide. According to one or more embodiments, the base layer 201 may be an organic layer including an epoxy-based resin, an acrylic-based resin, or an imide-based resin. The base layer 201 may have a single-layer structure or a multi-layer structure of layers stacked in the third direction DR3. According to one or more embodiments, the sensor layer 200 may not include the base layer 201.

Each of the first conductive layer 202 and the second conductive layer 204 may have a single-layer structure or a multi-layer structure of layers stacked in the third direction DR3.

Each of the first and second conductive layers 202 and 204 having the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), indium zinc tin oxide (IZTO), or the like. In addition, the transparent conductive layer may include conductive polymer such as poly(3,4-ethylenedioxythiophene) (PEDOT), metal nanowire, graphene, or the like.

Each of the first and second conductive layers 202 and 204 having the multi-layer structure may include metal layers. The metal layers may have a three-layer structure of titanium/aluminum/titanium. The conductive layer having the multi-layer structure may include at least one metal layer and at least one transparent conductive layer.

The first conductive layer 202 may have a thickness that is greater than or equal to a thickness of the second conductive layer 204. When the thickness of the first conductive layer 202 is greater than the thickness of the second conductive layer 204, a resistance of components (e.g., an electrode, a pattern, or a bridge pattern) included in the first conductive layer 202 may be reduced. In addition, because the first conductive layer 202 is located below the second conductive layer 204, a probability that the components included in the first conductive layer 202 are recognized due to a reflection of external light may be lower than a probability that components included in the second conductive layer 204 are recognized even when the thickness of the first conductive layer 202 increases.

At least one of the intermediate insulating layer 203 or the cover insulating layer 205 may include an inorganic layer. The inorganic layer may include at least one of aluminum oxide, titanium oxide, silicon oxide, silicon nitride, silicon oxynitride, zirconium oxide, or hafnium oxide.

At least one of the intermediate insulating layer 203 or the cover insulating layer 205 may include an organic layer. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, or a perylene-based resin.

In the above descriptions, it is explained that the sensor layer 200 includes the first conductive layer 202 and the second conductive layer 204, that is, a total of two conductive layers, although the present disclosure should not be limited thereto or thereby. As an example, the sensor layer 200 may include three or more conductive layers.

FIG. 7B is a cross-sectional view of some components of the sensor layer 200 (refer to FIG. 7A) according to one or more embodiments of the present disclosure.

Referring to FIGS. 7A and 7B, a second mesh line MS2 included in the second conductive layer 204 may have a second width 204wt that is greater than or equal to a first width 202wt of a first mesh line MS1 included in the first conductive layer 202. When a user USR views the first mesh line MS1 and the second mesh line MS2 from a side of the sensor layer 200, a probability that the first mesh line MS1 is being perceived by the user USR may be reduced because the width of the first mesh line MS1 is smaller than that of the second mesh line MS2.

Each of the first mesh line MS1 and the second mesh line MS2 may include first metal layers M1 and a second metal layer M2 located between the first metal layers M1. As an example, the first metal layers M1 may include titanium (Ti), and the second metal layer M2 may include aluminum (Al), although this is merely an example.

A first thickness TK1 of the second metal layer M2 of the first mesh line MS1 and a second thickness TK2 of the second metal layer M2 of the second mesh line MS2 may be substantially the same as each other, although the present disclosure should not be particularly limited. As an example, the first thickness TK1 may be greater than the second thickness TK2, or the second thickness TK2 may be greater than the first thickness TK1. Each of the first thickness TK1 and the second thickness TK2 may be about 1000 angstroms or more (e.g., about 6000 angstroms).

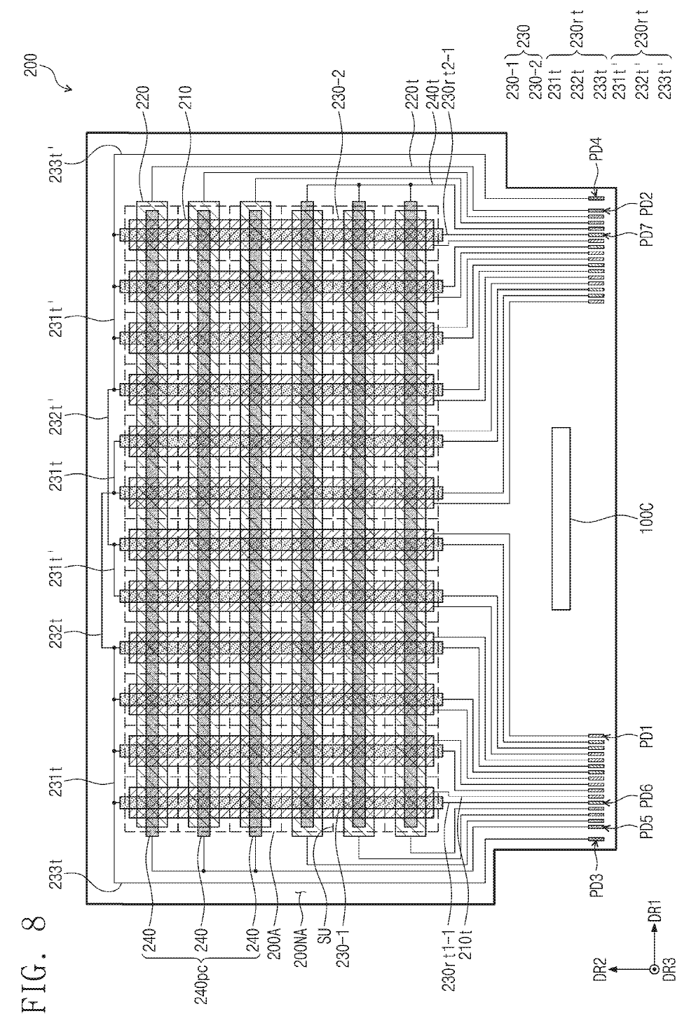

FIG. 8 is a plan view of the sensor layer 200 according to one or more embodiments of the present disclosure.

Referring to FIG. 8, the sensor layer 200 may include the sensing area 200A, and the peripheral area 200NA adjacent to the sensing area 200A, which are defined therein.

The sensor layer 200 may include a plurality of first electrodes 210, a plurality of second electrodes 220, a plurality of third electrodes 230, and a plurality of fourth electrodes 240, which are arranged in the sensing area 200A.

Each of the first electrodes 210 may cross the second electrodes 220. Each of the first electrodes 210 may extend in the second direction DR2, and the first electrodes 210 may be arranged spaced apart from each other in the first direction DR1. Each of the second electrodes 220 may extend in the first direction DR1, and the second electrodes 220 may be arranged spaced apart from each other in the second direction DR2. A sensing unit SU of the sensor layer 200 may be an area where one first electrode 210 cross one second electrode 220.

FIG. 8 illustrates twelve first electrodes 210, six second electrodes 220, and seventy-two sensing units SU merely as a representative example, although the number of the first electrodes 210 and the number of the second electrodes 220 should not be limited thereto or thereby.

Each of the third electrodes 230 may extend in the second direction DR2, and the third electrodes 230 may be arranged spaced apart from each other in the first direction DR1. One third electrode 230 may overlap at least a portion of one first electrode 210. A capacitance (or a coupling capacitance) between one first electrode 210 and one third electrode 230 may be controlled by adjusting the overlapping area between the one first electrode 210 and the one third electrode 230.

The third electrodes 230 may include a plurality of first charging electrodes 230-1 and a plurality of second charging electrodes 230-2. The first charging electrodes 230-1 may be arranged in the first direction DR1, and the second charging electrodes 230-2 may be arranged in the first direction DR1. The first charging electrodes 230-1 may be electrically connected to each other, and the second charging electrodes 230-2 may be electrically connected to each other. The first charging electrodes 230-1 may be electrically insulated from the second charging electrodes 230-2.

At least one first charging electrode 230-1 among the first charging electrodes 230-1 may be arranged between at least one second charging electrode 230-2 among the second charging electrodes 230-2 and the other (e.g., a reminder of) second charging electrodes 230-2. As an example, referring to FIG. 8, two first charging electrodes 230-1 among the first charging electrodes 230-1 may be arranged between two second charging electrodes 230-2 among the second charging electrodes 230-2 and remaining four second charging electrodes 230-2, although the present disclosure should not be limited thereto or thereby. The arrangement relationship between the first charging electrodes 230-1 and the second charging electrodes 230-2 may be modified in various ways.

According to the present disclosure, a portion of the first charging electrodes 230-1 and a portion of the second charging electrodes 230-2 may be arranged to cross with each other. Accordingly, a current loop that generates a magnetic field to charge the pen PN (refer to FIG. 6) may be formed (or defined) in an area where the first charging electrodes 230-1 of the sensor layer 200 are arranged, an area where the second charging electrodes 230-2 are arranged, and areas between the portion of the first charging electrodes 230-1 and the portion of the second charging electrodes 230-2. In addition, the current loop using the first charging electrodes 230-1 and the current loop using the second charging electrodes 230-2 may be concurrently or substantially simultaneously formed. Therefore, the charging performance of the pen PN (refer to FIG. 6) may be improved. As an example, the charging speed of the pen PN (refer to FIG. 6) and the charge rate of the pen PN (refer to FIG. 6) may be improved, and thus, linearity and accuracy for inputs generated by the pen PN (refer to FIG. 6) may be improved. That is, the touch performance of the electronic device 1000 (refer to FIG. 2A) may be improved.

According to one or more embodiments, in a charge-driving mode, the sensor driver 200C (refer to FIG. 6) may concurrently or substantially simultaneously drive the first charging electrodes 230-1 and the second charging electrodes 230-2. According to one or more embodiments, in the charge-driving mode, the sensor driver 200C (refer to FIG. 6) may drive only one of the first charging electrodes 230-1 and the second charging electrodes 230-2. As an example, the first charging electrodes 230-1 and the second charging electrodes 230-2 may be driven in a time-division manner or in a selective-division manner. Accordingly, the current loop using the first charging electrodes 230-1 and the current loop using the second charging electrodes 230-2 may be formed separately.

When the first charging electrodes 230-1 and the second charging electrodes 230-2 are concurrently or substantially simultaneously driven in the charge-driving mode, the current loop by the first charging electrodes 230-1 and the current loop by the second charging electrodes 230-2 may be concurrently or substantially simultaneously formed. In addition, when the first charging electrodes 230-1 and the second charging electrodes 230-2 are driven in the time-division manner during the charge-driving mode, the sensor driver 200C (refer to FIG. 6) may apply a signal to the first charging electrodes 230-1 to form the current loop while not applying a signal to the second charging electrodes 230-2. Then, the signal may be applied to the second charging electrodes 230-2 to form the current loop while not applying to the first charging electrodes 230-1. When the first charging electrodes 230-1 and the second charging electrodes 230-2 are driven in the selective-division manner during the charge-driving mode, the signal may be provided to the first charging electrodes 230-1 or the second charging electrodes 230-2 corresponding to a location to which the input generated by the pen PN (refer to FIG. 6) is applied to form the current loop. In this case, the signal may not be provided to the first charging electrodes 230-1 or the second charging electrodes 230-2 arranged in an area where the pen PN is not located.

The fourth electrodes 240 may be arranged in the second direction DR2, and the fourth electrodes 240 may extend in the first direction DR1. One fourth electrode 240 may overlap at least a portion of one second electrode 220. A capacitance (or a coupling capacitance) between one second electrode 220 and fourth electrode 240 may be controlled by adjusting the overlapping area between the one second electrode 220 and the one fourth electrode 240.

According to one or more embodiments, at least some of the fourth electrodes 240 may be electrically connected to each other to form one electrode group 240pc. As an example, in FIG. 8, three fourth electrodes 240 are connected to the same trace line, for example, an auxiliary trace line 240t, to form one electrode group 240pc. Accordingly, FIG. 8 illustrates the structure in which two electrode groups 240pc are arranged in the second direction DR2. However, the number of the fourth electrodes 240 constituting one electrode group 240pc should not be limited thereto or thereby. As an example, the number of the fourth electrodes 240 constituting one electrode group 240pc may be six, and in this case, the sensor layer 200 may include only one electrode group 240pc. The fourth electrodes 240 may be referred to as auxiliary electrodes 240.

The sensor layer 200 may further include a plurality of first trace lines 210t arranged in the peripheral area 200NA, a plurality of first pads PD1 connected to the first trace lines 210t in a one-to-one correspondence, a plurality of second trace lines 220t, and a plurality of second pads PD2 connected to the second trace lines 220t in a one-to-one correspondence. The first trace lines 210t may be electrically connected to the first electrodes 210 in a one-to-one correspondence. The second trace lines 220t may be electrically connected to the second electrodes 220 in a one-to-one correspondence.

The sensor layer 200 may further include a first loop trace line 230rt1 arranged in the peripheral area 200NA, a third pad PD3 connected to one end of the first loop trace line 230rt1, a second loop trace line 230rt2, a fourth pad PD4 connected to one end of the second loop trace line 230rt2, auxiliary trace lines 240t, fifth pads PD5 connected to the auxiliary trace lines 240t in a one-to-one correspondence, first-first loop trace lines 230rt1-1, sixth pads PD6 connected to the first-first loop trace lines 230rt1-1 in a one-to-one correspondence, second-first loop trace lines 230rt2-1, and seventh pads PD7 connected to the second-first loop trace lines 230rt2-1 in a one-to-one correspondence.

The first loop trace line 230rt1 and the second loop trace line 230rt2 may be referred to as loop trace lines 230rt1 and 230rt2, the first-first loop trace lines 230rt1-1 and the second-first loop trace lines 230rt2-1 may be referred to as third trace lines 230rt1-1 and 230rt2-1, and the auxiliary trace lines 240t may be referred to as fourth trace lines 240t.

The first loop trace line 230rt1 may be electrically connected to the first charging electrodes 230-1. That is, the first loop trace line 230rt1 may be electrically connected to all the first charging electrodes 230-1.

The second loop trace line 230rt2 may be electrically connected to the second charging electrodes 230-2. That is, the second loop trace line 230rt2 may be electrically connected to all the second charging electrodes 230-2.

The first loop trace line 230rt1 may include a plurality of first portions 231t extending in the first direction DR1 and electrically connected to the first charging electrodes 230-1, a second portion 232t electrically connecting the first portions 231t and arranged between the first portions 231t, and a third portion 233t extending from one end of the first portions 231t along the second direction DR2.

The third portion 233t may extend in the same direction as the extension direction of the first charging electrodes 230-1 (e.g., the second direction DR2). The third portion 233tmay serve as the first charging electrode 230-1and may provide an effect as if the first charging electrode 230-1 is also arranged in the peripheral area 200NA. As an example, the third portion 233t and one of the first charging electrodes 230-1 may form a coil. Accordingly, a pen located at an area adjacent to the peripheral area 200NA may be sufficiently charged by a loop including the third portion 233t.

The second loop trace line 230rt2 may include a plurality of first-first portions 231t’ extending in the first direction DR1 and electrically connected to the second charging electrodes 230-2, a second-first portion 232t’ electrically connecting the first-first portions 231t’ and arranged between the first-first portions 231t’, and a third-first portion 233t’ extending from one end of the first-first portions 231t’ along the second direction DR2.

The third-first portion 233t’ may extend in the same direction as the extension direction of the second charging electrodes 230-2 (e.g., the second direction DR2). The third-first portion 233t’ may serve as the second charging electrode 230-2 and may provide an effect as if the second charging electrode 230-2 is also arranged in the peripheral area 200NA. As an example, the third-first portion 233t’ and one of the second charging electrodes 230-2 may form a coil. Therefore, a pen located at an area adjacent to the peripheral area 200NA may be sufficiently charged by a loop including the third-first portion 233t’.

The first loop trace line 230rt1 may be insulated from the second loop trace line 230rt2 while crossing the second loop trace line 230rt2. As an example, the second portion 232t of the first loop trace line 230rt1 may be insulated from the second-first portion 232t’ of the second loop trace line 230rt2 while crossing the second-first portion 232t’ of the second loop trace line 230rt2. Accordingly, the first charging electrodes 230-1 electrically connected to the first loop trace line 230rt1 may be electrically insulated from the second charging electrodes 230-2 electrically connected to the second loop trace line 230rt2.

According to the present disclosure, the first charging electrodes 230-1 and the second charging electrodes 230-2 of the sensor layer 200 may be electrically connected to the first loop trace line 230rt1 and the second loop trace line 230rt2, respectively. Therefore, compared to a case where all of the third electrodes 230 are connected to a single loop trace line, in a case where some of the third electrodes 230 and remaining third electrodes 230 are connected to two first and second loop trace lines 230rt1 and 230rt2, respectively, each of the first and second loop trace lines 230rt1 and 230rt2 may have a length that is less than a length of the single loop trace line. Accordingly, a resistance of each of the first and second loop trace lines 230rt1 and 230rt2 may be reduced compared to a resistance of the single loop trace line.

The first-first loop trace lines 230rt1-1 may be connected to the first charging electrodes 230-1 in a one-to-one correspondence. That is, the number of the first-first loop trace lines 230rt1-1 may correspond to the number of the first charging electrodes 230-1. The second-first loop trace lines 230rt2-1 may be connected to the second charging electrodes 230-2 in a one-to-one correspondence. That is, the number of the second-first loop trace lines 230rt2-1 may correspond to the number of the second charging electrodes 230-2. FIG. 8 illustrates six first-first loop trace lines 230rt1-1, six first charging electrodes 230-1, six second-first loop trace lines 230rt2-1, and six second charging electrodes 230-2 as a representative example. However, this is merely an example, and the present disclosure should not be limited thereto or thereby. As an example, in one or more embodiments, one first-first loop trace line 230rt1-1 may be electrically connected to two first charging electrodes 230-1 arranged consecutively adjacent to each other, and one second-first loop trace line 230rt2-1 may be electrically connected to two second charging electrodes 230-2 arranged consecutively adjacent to each other.

The auxiliary trace lines 240t may be spaced apart from each other, and the sensing area 200A may be located between the auxiliary trace lines 240t. The auxiliary trace lines 240t may be electrically connected to the electrode groups 240pc in a one-to-one correspondence. FIG. 8 illustrates two electrode groups 240pc as a representative example. The auxiliary trace line 240t connected to one electrode group 240pc and the auxiliary trace line 240t connected to the other electrode group 240pc may be spaced apart from each other, and the sensing area 200A may be located between the auxiliary trace lines 240t. However, the present disclosure should not be particularly limited, and the auxiliary trace lines 240t may be referred to as trace lines.

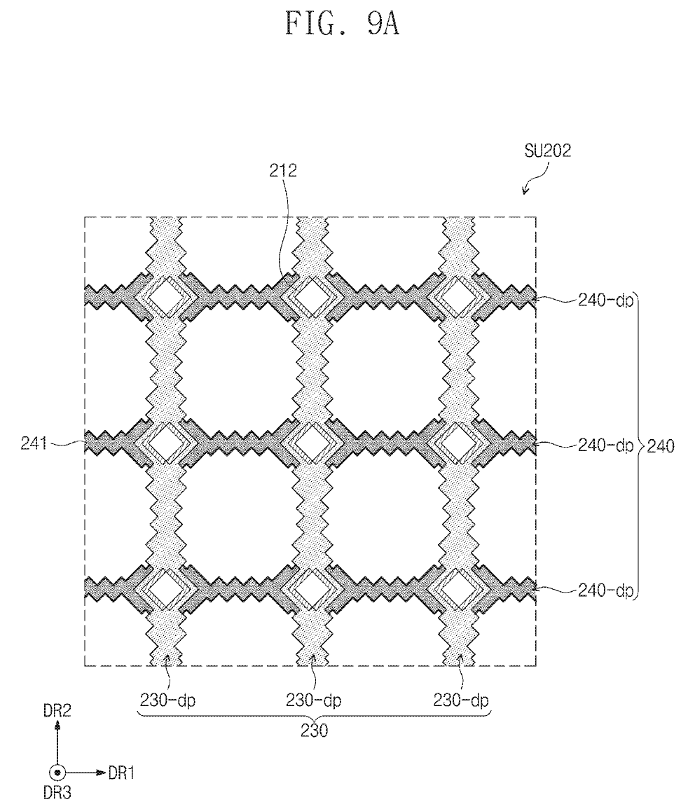

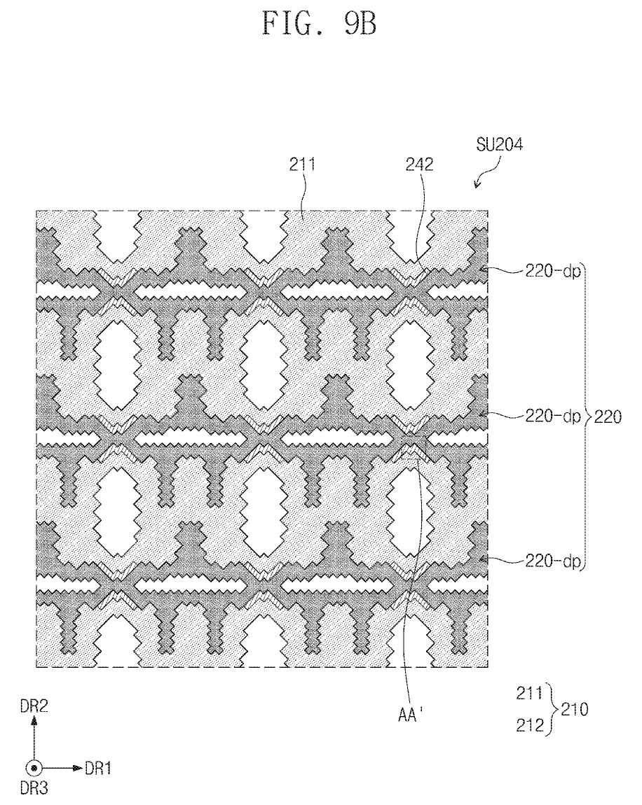

FIG. 9A is a plan view of a first conductive layer SU202 of the sensing unit SU (refer to FIG. 8) according to one or more embodiments of the present disclosure.

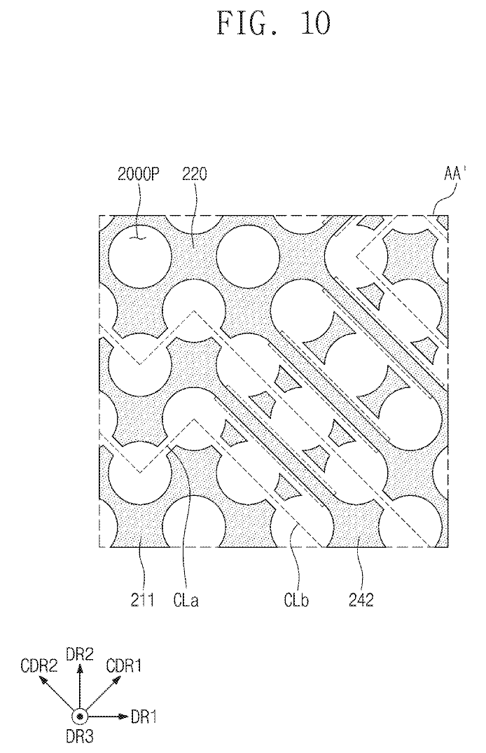

FIG. 9B is a plan view of a second conductive layer SU204 of the sensing unit SU (refer to FIG. 8) according to one or more embodiments of the present disclosure. FIG. 10 is an enlarged plan view of an area AA’ shown in FIG. 9B.

In FIGS. 9A and 9B, the shape of a mesh structure is not depicted, and boundaries of each component are illustrated simply as lines. That is, the lines illustrated in FIGS. 9A and 9B may be understood as corresponding to the lines from which the mesh structure of FIG. 10 is removed, and lines CLa and CLb are depicted as dashed lines.

The shape of the sensing unit SU and the mesh structure shown in FIGS. 9A, 9B, and 10 are merely an example, and the present disclosure should not be limited thereto or thereby. The shape of the sensing unit SU and the mesh structure may be modified in various ways.

Referring to FIGS. 9A and 9B, the first electrode 210 may include a plurality of first patterns 211, and a plurality of first bridge patterns 212 electrically connected to the first patterns 211. The first patterns 211 arranged spaced apart from each other in the second direction DR2 may be electrically connected to each other by the first bridge patterns 212. The first patterns 211 may be included in the second conductive layer SU204, and the first bridge patterns 212 may be included in the first conductive layer SU202.

In one first electrode 210, two first patterns 211 adjacent to each other in the second direction DR2 may be electrically connected to each other by six first bridge patterns 212. An increase in the number of the first bridge patterns 212 arranged in the first direction DR1 crossing the second direction DR2, which is the extension direction of the first electrode 210, may correspond to an increase in the number of signal paths. Accordingly, as the number of the signal paths increases, the resistance of the first electrode 210 may decrease. As a result, the sensing sensitivity of the sensor layer 200 may be improved.

The second electrode 220 may include a plurality of first division electrodes 220-dp spaced apart from each other in the second direction DR2. Each of the first division electrodes 220-dp may extend in the first direction DR1, and the first division electrodes 220-dp may be spaced apart from each other in the second direction DR2. The first division electrodes 220-dp may be included in the second conductive layer SU204. Three first division electrodes 220-dp included in one second electrode 220 may be connected to one second trace line 220t (refer to FIG. 8).

The third electrode 230 may include a plurality of second division electrodes 230-dp spaced apart from each other in the first direction DR1. Each of the second division electrodes 230-dp may extend in the second direction DR2. The second division electrodes 230-dp may be spaced apart from each other in the first direction DR1. When viewed in the third direction DR3, the second division electrodes 230-dp may overlap at least a portion of the first patterns 211.

The fourth electrode 240 may include a plurality of third division electrodes 240-dp spaced apart from each other in the second direction DR2. Each of the third division electrodes 240-dp may extend in the first direction DR1. Each of the third division electrodes 240-dp may include a plurality of second patterns 241, and a plurality of second bridge patterns 242 electrically connected to the second patterns 241. The second patterns 241 and the second bridge patterns 242 may be electrically connected to each other via contact holes defined through the intermediate insulating layer 203 (refer to FIG. 7A). Two second patterns 241 adjacent to each other may be spaced apart from each other, and one second division electrode 230-dp and two first bridge patterns 212 may be arranged between the two second patterns 241 adjacent to each other.

FIGS. 9A and 9B illustrate the structure in which one sensing unit SU includes three first division electrodes 220-dp, three second division electrodes 230-dp, and three third division electrodes 240-dp as a representative example, although the present disclosure should not be particularly limited. As an example, each of the number of the first division electrodes 220-dp, the number of the second division electrodes 230-dp, and the number of the third division electrodes 240-dp, which are included in one sensing unit SU, may be one, two, or four or more.

According to one or more embodiments, a first capacitor may be defined between the first electrode 210 and the third electrode 230, and a second capacitor may be defined between the second electrode 220 and the fourth electrode 240. A first capacitance of the first capacitor and a second capacitance of the second capacitance may be adjusted by the overlapping area between the first electrode 210 and the third electrode 230 and the overlapping area between the second electrode 220 and the fourth electrode 240.

As the first and second capacitances increase, an amount of induced current transferred from the third electrode 230 to the first electrode 210 may increase, and an amount of induced current transferred from the fourth electrode 240 to the second electrode 220 may increase. Accordingly, as the first and second capacitances increase, a pen-sensing performance of the sensor layer 200 may be improved. In addition, during the touch sensing mode, the first and second capacitances may act as a load. Accordingly, as the first and second capacitances decrease, the touch sensing performance may be improved.

The overlapping area between the first electrode 210 and the third electrode 230, and the overlapping area between the second electrode 220 and the fourth electrode 240, may be suitably adjusted. Accordingly, the sensor layer 200 may have capacitances at an appropriate level taking into account the touch sensitivity and a pen sensitivity. As a result, the pen sensitivity and the touch sensitivity of the electronic device 1000 (refer to FIG. 2A) may be improved.

The area occupied by the components included in the first electrode 210 and the second electrode 220 in the second conductive layer SU204 within one sensing unit SU may be larger than the area occupied by the components included in the third electrode 230 and the fourth electrode 240. The change in capacitance caused by the first input 2000 (refer to FIG. 4) may be larger as the distance decreases. Accordingly, the components to sense the first input 2000 (refer to FIG. 4) may be arranged with a larger area in a layer that is relatively closer to the surface of the electronic device 1000 (refer to FIG. 1A). As a result, the touch performance may be improved.

Referring to FIGS. 9A, 9B, and 10, each of the first, second, third, and fourth electrodes 210, 220, 230, and 240 may have the mesh structure. The mesh structure may be a structure through which a plurality of openings 200OP is defined. FIG. 10 illustrates the openings 200OP each having a circular shape with a selected curvature as a representative example, but the present disclosure should not be particularly limited. As an example, each of the openings 200OP may have a variety of shapes such as a square shape, a polygonal shape, or an irregular shape.

FIG. 10 illustrates a portion of each of the first pattern 211, the second bridge pattern 242, and the second electrode 220, which are arranged in the second conductive layer SU204. The first pattern 211, the second bridge pattern 242, and the second electrode 220 may be electrically insulated from each other. As an example, the first pattern 211, the second bridge pattern 242, and the second electrode 220 may be electrically insulated from each other by a first line CLa extending in a first cross direction CDR1 crossing the first direction DR1 and the second direction DR2, and a second line CLb extending in a second cross direction CDR2 crossing the first cross direction CDR1. One portion of the conductive layer and the other portion of the conductive layer may be spaced apart from each other, and the first line CLa and the second line CLb may be arranged between the one portion and the other portion of the conductive layer.

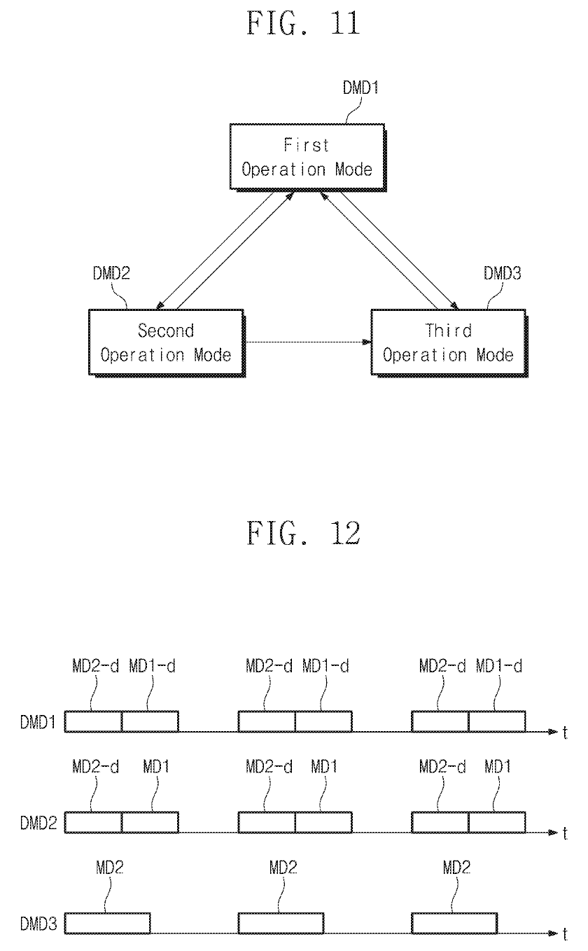

FIG. 11 is a view illustrating an operation of the sensor driver 200C (refer to FIG. 6) according to one or more embodiments of the present disclosure.

Referring to FIGS. 6 and 11, the sensor driver 200C may be selectively driven in one of a first operation mode DMD1, a second operation mode DMD2, and a third operation mode DMD3.

The first operation mode DMD1 may be referred to as a touch-and-pen-standby mode, the second operation mode DMD2 may be referred to as a touch-active-and-pen-standby mode, and the third operation mode DMD3 may be referred to as a pen-active mode. The first operation mode DMD1 may be a mode that waits for the first input 2000 and the second input 3000. The second operation mode DMD2 may be a mode that senses the first input 2000 and waits for the second input 3000. The third operation mode DMD3 may be a mode that senses the second input 3000.

The sensor driver 200C may be first driven in the first operation mode DMD1. When the first input 2000 is sensed in the first operation mode DMD1, the driving mode of the sensor driver 200C may be switched (or changed) to the second operation mode DMD2. When the second input 3000 is sensed in the first operation mode DMD1, the driving mode of the sensor driver 200C may be switched (or changed) to the third operation mode DMD3.

When the second input 3000 is sensed in the second operation mode DMD2, the driving mode of the sensor driver 200C may be switched (or changed) to the third operation mode DMD3. When the first input 2000 is released (or not sensed) in the second operation mode DMD2, the driving mode of the sensor driver 200C may be switched (or changed) to the first operation mode DMD1. When the second input 3000 is released (or not sensed) in the third operation mode DMD3, the driving mode of the sensor driver 200C may be switched (or changed) to the first operation mode DMD1.

FIG. 12 is a view illustrating an operation of the sensor driver 200C (refer to FIG. 6) according to one or more embodiments of the present disclosure.

Referring to FIGS. 6, 11, and 12, the operations in the first, second, and third operation modes DMD1, DMD2, and DMD3 are illustrated in the order of time t.

In the first operation mode DMD1, the sensor driver 200C may be repeatedly driven in a second mode MD2-d and a first mode MD1-d. During the second mode MD2-d, the sensor layer 200 may be scan-driven to sense the second input 3000. During the first mode MD1-d, the sensor layer 200 may be scan-driven to sense the first input 2000. FIG. 12 illustrates the sensor driver 200C operating in the first mode MD1-d after the second mode MD2-d, but the operating order of the sensor driver 200C should not be limited thereto or thereby.

In the second operation mode DMD2, the sensor driver 200C may be repeatedly driven in the second mode MD2-d and a first mode MD1. During the second mode MD2-d, the sensor layer 200 may be scan-driven to sense the second input 3000. During the first mode MD1, the sensor layer 200 may be scan-driven to detect coordinates of the input by the first input 2000.

In the third operation mode DMD3, the sensor driver 200C may be driven in a second mode MD2. During the second mode MD2, the sensor layer 200 may be scan-driven to detect coordinates of the input by the second input 3000. In the third operation mode DMD3, the sensor driver 200C might not be driven in the first mode MD1-d or MD1 until the second input 3000 is released (or not sensed).

Referring to FIG. 8, the third electrodes 230 and the fourth electrodes 240 may all be grounded or may receive a constant voltage in the first mode MD1-d and the first mode MD1. According to one or more embodiments, both the third electrodes 230 and the fourth electrodes 240 may be floated (or electrically floated) in the first mode MD1-d and the first mode MD1. According to one or more embodiments, a signal that is in-phase with a transmission signal provided to the first electrodes 210 may be applied to the third electrodes 230 and the fourth electrodes 240 in the first mode MD1-d and the first mode MD1. In this case, a touch noise entering through the third electrodes 230 and the fourth electrodes 240 may be reduced or prevented.

In the second mode MD2-d and the second mode MD2, one ends of the third electrodes 230 and one ends of the fourth electrodes 240 may be floated. In addition, in the second mode MD2-d and the second mode MD2, the other ends of the third electrodes 230 and the other ends of the fourth electrodes 240 may be grounded or floated. Accordingly, the compensation for the sensing signal may be maximized by the coupling between the first electrodes 210 and the third electrodes 230, and the coupling between the second electrodes 220 and the fourth electrodes 240.

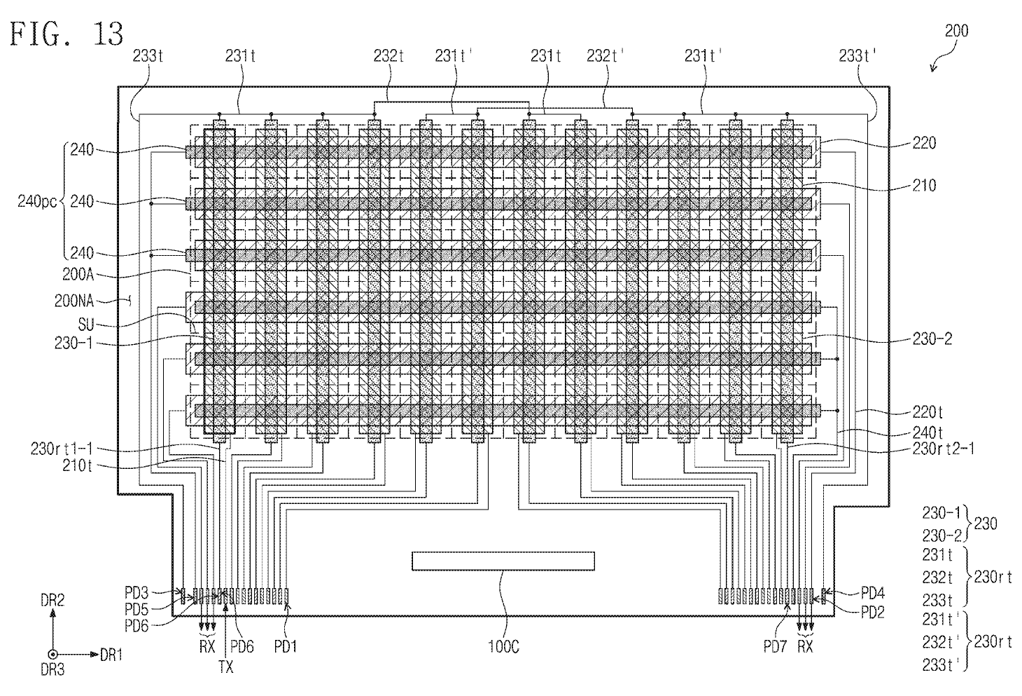

FIG. 13 is a view illustrating the first modes MD1-d and MD1 according to one or more embodiments of the present disclosure.

Referring to FIGS. 6, 12, and 13, the first mode MD1-d of the first operation mode DMD1 and the first mode MD1 of the second operation mode DMD2 may include a mutual capacitance detection mode. FIG. 13 is a view illustrating the mutual capacitance detection mode in the first mode MD1-d of the first operation mode DMD1 and the first mode MD1 of the second operation mode DMD2.

In the mutual capacitance detection mode, the sensor driver 200C may sequentially apply a transmission signal TX to the first electrodes 210 and may detect coordinates of the first input 2000 using a reception signal RX detected through the second electrodes 220. As an example, the sensor driver 200C may sense a variation in mutual capacitance between the first electrodes 210 and the second electrodes 220 to calculate input coordinates.

FIG. 13 illustrates a structure in which the transmission signal TX is applied to one first electrode 210 and the reception signal RX is output from the second electrodes 220 as a representative example. To clearly depict the signal, one of the first electrodes 210, to which the transmission signal TX is provided, is highlighted in bold in FIG. 13. The sensor driver 200Cmay sense a variation in capacitance between the first electrode 210 and each of the second electrodes 220 to calculate the input coordinates with respect to the first input 2000.

According to one or more embodiments of the present disclosure, at least one of the first mode MD1-d of the first operation mode DMD1 or the first mode MD1 of the second operation mode DMD2 may further include a self-capacitance detection mode. The sensor driver 200C may output driving signals to the first electrodes 210 and the second electrodes 220 in the self-capacitance detection mode and may sense a variation in capacitance of each of the first electrodes 210 and each of the second electrodes 220 to calculate input coordinates.

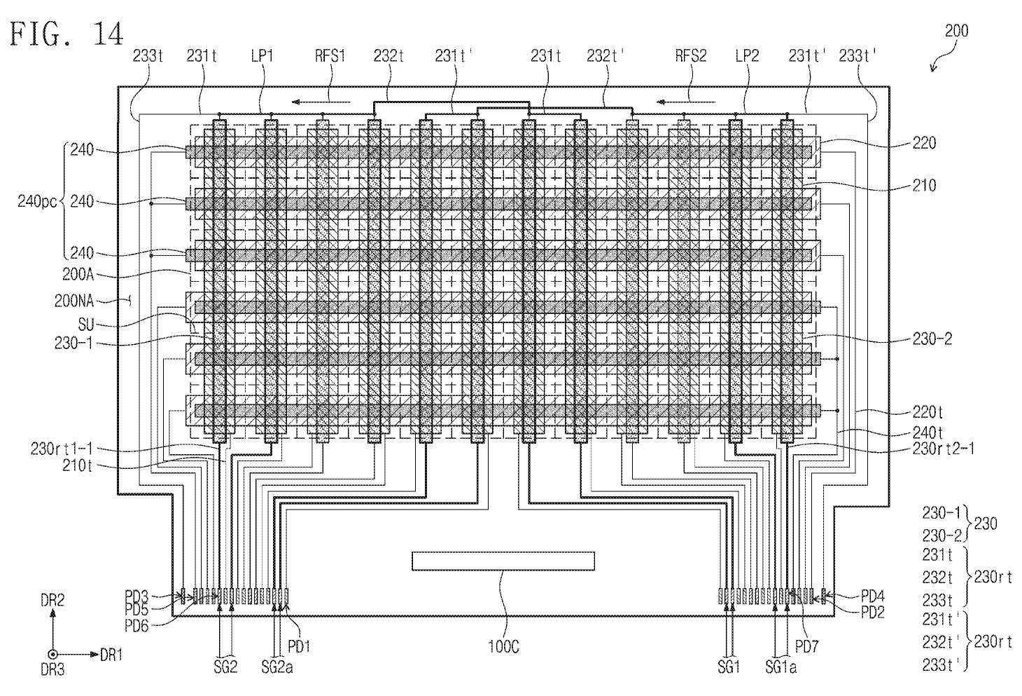

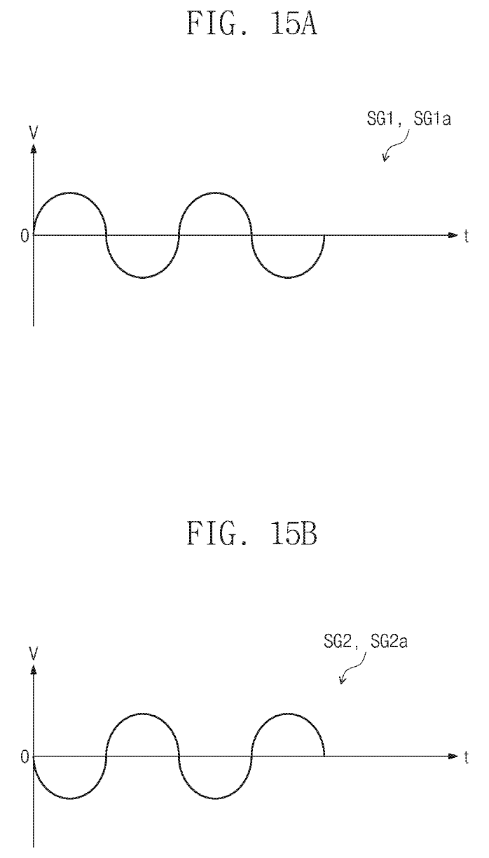

FIG. 14 is a view illustrating a second mode (e.g., the charge-driving mode) according to one or more embodiments of the present disclosure. FIG. 15A is a graph illustrating a waveform of a first signal SG1 and a first-first signal SG1aaccording to one or more embodiments of the present disclosure. FIG. 15B is a graph illustrating a waveform of a second signal SG2 and a second-first signal SG2a according to one or more embodiments of the present disclosure.

Referring to FIGS. 12, 14, 15A, and 15B, the second mode may include the charge-driving mode. The charge-driving mode may include a searching charge-driving mode and a tracking charge-driving mode. However, this is merely an example, and the charge-driving mode may include a single charge-driving mode.

The searching charge-driving mode may be a driving mode before sensing a position of the pen. According to the present disclosure, the sensor layer 200 may include the first charging electrodes 230-1 and the second charging electrodes 230-2. In this case, the first signal SG1 or the second signal SG2 may be sequentially applied to the first charging electrodes 230-1, and concurrently or substantially simultaneously, the first-first signal SG1a or the second-first signal SG2a may be sequentially applied to the second charging electrodes 230-2. That is, in the searching charge-driving mode, the area where the first charging electrodes 230-1 are arranged and the area where the second charging electrodes 230-2 are arranged in the sensor layer 200 may be sequentially and concurrently or substantially simultaneously scanned, although the present disclosure should not be limited thereto or thereby. According to one or more embodiments, the first signal SG1 or the second signal SG2 may be applied only to the first charging electrodes 230-1, or the first-first signal SG1a or the second-first signal SG2a may be applied only to the second charging electrodes 230-2. That is, in the searching charge-driving mode, the area where the first charging electrodes 230-1 are arranged and the area where the second charging electrodes 230-2 are arranged in the sensor layer 200 may be driven in the time-division manner or the selective-division manner.

When the pen PN is sensed in the searching charge-driving mode, the sensor layer 200 may be driven in the tracking charge-driving mode. As an example, in the tracking charge-driving mode, the sensor driver 200C may sequentially apply either the first signal SG1 and the second signal SG2 or the first-first signal SG1a and the second-first signal SG2a to an area overlapping the location where the pen PN is sensed rather than to the entire sensor layer 200.

According to one or more embodiments, in the charge-driving mode, the sensor driver 200C may apply the signal to at least a portion of the first charging electrodes 230-1 to form a first loop LP1. As an example, the sensor driver 200C may apply the first signal SG1 to at least one of the sixth pads PD6, and may apply the second signal SG2 to at least another one of the sixth pads PD6 to form the first loop LP1. The second signal SG2 may be a phase-inverted version of the first signal SG1. As an example, the first signal SG1 may be a sinusoidal signal.

According to one or more embodiments, in the charge-driving mode, the sensor driver 200C may apply signals to at least a portion of the second charging electrodes 230-2 to form a second loop LP2. As an example, the sensor driver 200C may apply the first-first signal SG1a to at least one of the seventh pads PD7, and may apply the second-first signal SG2a to at least another one of the seventh pads PD7 to form the second loop LP2. The second-first signal SG2a may be a phase-inverted version of the first-first signal SG1a. As an example, the first-first signal SG1a may be a sinusoidal signal. That is, the sensor driver 200C may be configured to concurrently or substantially simultaneously form two loops LP1 and LP2 in the sensor layer 200. That is, the first loop LP1 and the second loop LP2 may be concurrently or substantially simultaneously driven. However, the present disclosure should not be limited thereto or thereby, and only one of the first loop LP1 and the second loop LP2 may be driven. As an example, the sensor driver 200C may be configured to allow the two loops LP1 and LP2 of the sensor layer 200 to be time-division driven or to be selective-division driven.

Because the first signal SG1 and the second signal SG2 are applied to at least two pads among the pads connected to the first charging electrodes 230-1, a first current RFS1 may have the first loop LP1 flowing from one pad to another pad, and because the first-first signal SG1a and the second-first signal SG2a are applied to at least two pads among the pads connected to the second charging electrodes 230-2, a second current RFS2 may have the second loop LP2 flowing from one pad to another pad.

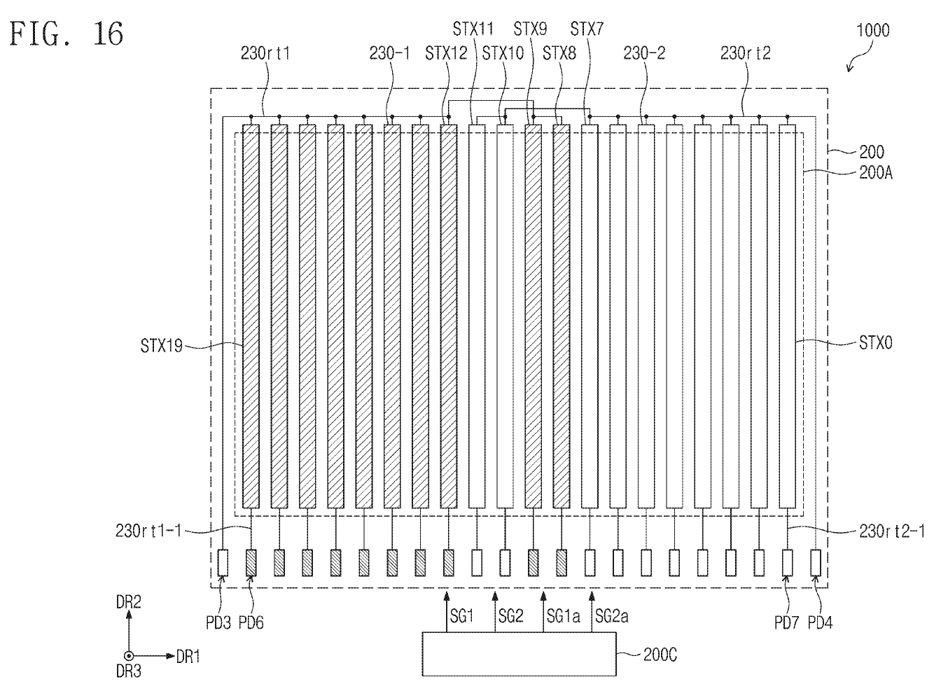

According to the present disclosure, because the first loop LP1 and the second loop LP2 are concurrently or substantially simultaneously formed, a time required to scan the entire area of the sensor layer 200 may be reduced by more than half compared to the case where only one loop is formed. Therefore, in the charge-driving mode, the touch performance of the electronic device 1000 (refer to FIG. 2A) may be improved. The forming of the first loop LP1 and the second loop LP2 will be described in detail with reference to FIG. 16. Hereinafter, the first-first signal SG1a and the second-first signal SG2a may be referred to as the first signal SG1a and the second signal SG2a, respectively.

Because the first signals SG1 and SG1a and the second signals SG2 and SG2a are sinusoidal signals respectively having inverted phase from each other, directions of the first current RFS1 and the second current RFS2 may change periodically. According to one or more embodiments of the present disclosure, the first signals SG1 and SG1a and the second signals SG2 and SG2a may be square wave signals having respectively inverted phases.

When the first signals SG1 and SG1a and the second signals SG2 and SG2a have inverted phase, a noise induced in the display layer 100 (refer to FIG. 4) by the first signals SG1 and SG1a may be canceled out by a noise induced by the second signals SG2 and SG2a. Accordingly, a flicker phenomenon may be reduced or prevented from occurring in the display layer 100, and the display quality of the display layer 100 may be improved.

According to one or more embodiments of the present disclosure, the first signals SG1 and SG1a may be the sinusoidal signal, although the present disclosure should not be limited thereto or thereby, and the first signals SG1 and SG1a may be the square wave signal. The second signals SG2 and SG2a may have a constant voltage. As an example, the second signals SG2 and SG2a may be a ground voltage. That is, the pads to which the second signals SG2 and SG2a are applied may be considered as grounded. Even in this case, the first current RFS1 and the second current RFS2 may flow from one pad to another pad. In addition, even when another pad is grounded, the direction of the first current RFS1 and the second current RFS2 may change periodically because the first signals SG1 and SG1a are the sinusoidal signal or the square wave signal.

FIG. 14 illustrates the case where the first current RFS1 flows through the first loop LP1 defined by the two sixth pads PD6, two first-first loop trace lines 230rt1-1 connected to the two sixth pads PD6, two first charging electrodes 230-1, a portion of the first loop trace line 230rt1, two other first charging electrodes 230-1, two other first-first loop trace lines 230rt1-1 connected to two other sixth pads PD6, and the two other sixth pads PD6 as a representative example.

FIG. 14 illustrates the case where the second current RFS2 flows through the second loop LP2 defined by two seventh pads PD7, two second-first loop trace lines 230rt2-1 connected to the two seventh pads PD7, two second charging electrode 230-2, a portion of the second loop trace line 230rt2, two other second charging electrodes 230-2, two other second-first loop trace lines 230rt2-1 connected to two other seventh pads PD7, and the two other seventh pads PD7 as a representative example.

The third portion 233t of the first loop trace line 230rt1 and the third-first portion 233t’ of the second loop trace line 230rt2 may serve as the first charging electrode 230-1 and the second charging electrode 230-2, respectively. Accordingly, the first signal SG1 or the second signal SG2 may be applied to the third pad PD3 connected to the third portion 233t of the first loop trace line 230rt1, and the first signal SG1a or the second signal SG2a may be applied to the fourth pad PD4 connected to the third-first portion 233t’ of the second loop trace line 230rt2. That is, the first loop LP1 may include the third portion 233t of the first loop trace line 230rt1, and the second loop LP2 may include the third-first portion 233t’ of the second loop trace line 230rt2, although the present disclosure should not be limited thereto or thereby. According to one or more embodiments, components of the third portion 233t of the first loop trace line 230rt1, the third pad PD3 connected to the third portion 233t of the first loop trace line 230rt1, the third-first portion 233t’ of the second loop trace line 230rt2, and the fourth pad PD4 connected to the third-first portion 233t’ of the second loop trace line 230rt2 may be omitted. However, the present disclosure should not be limited thereto or thereby, and the components of the first loop LP1 and the second loop LP2 may be modified in various ways.

The first loop LP1 and the second loop LP2 may have a coil shape. Accordingly, a resonant circuit of the pen PN may be charged by a magnetic field formed by the first loop LP1 and the second loop LP2 in the charge-driving mode of the second mode. Accordingly, the electronic device 1000 (refer to FIG. 2A) may charge the pen PN using the sensor layer 200. Therefore, because there is no need to separately add a component including a coil to charge the pen PN, increases in thickness and weight and reduction in flexibility of the electronic device 1000 may not occur.

In the charge-driving mode, the first electrodes 210, the second electrodes 220, and the fourth electrodes 240 may be grounded, may receive the constant voltage, or may be electrically floated. For example, the first electrodes 210, the second electrodes 220, and the fourth electrodes 240 may be floated. In this case, the first current RFS1 and the second current RFS2 may not flow to the first electrodes 210, the second electrodes 220, and the fourth electrodes 240.

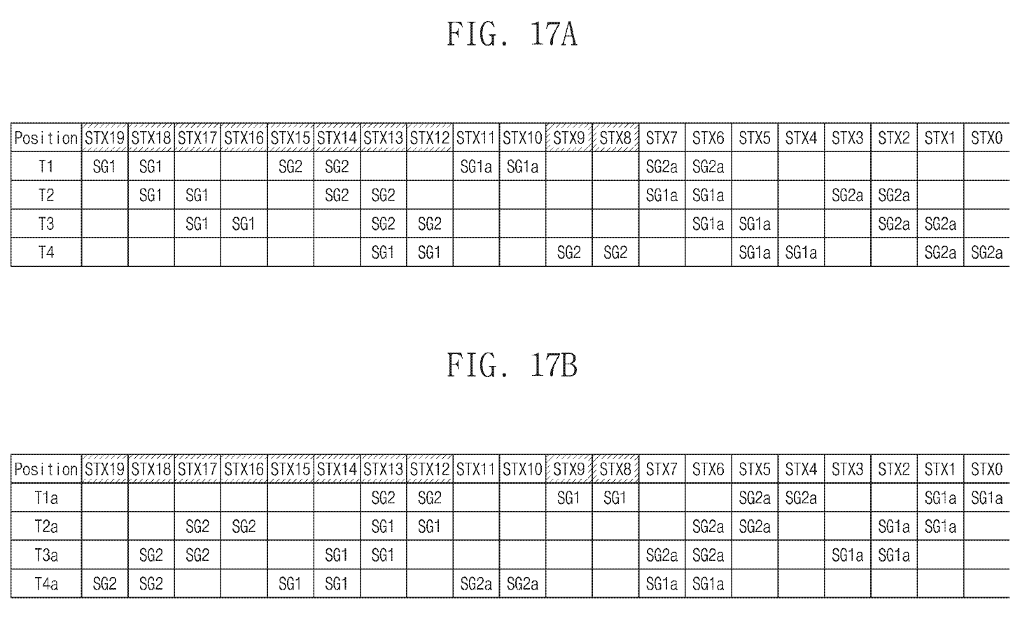

FIG. 16 is a view illustrating a second mode (e.g., a charge-driving mode) according to one or more embodiments of the present disclosure. FIG. 17A is a view illustrating the first signals SG1 and SG1a and the second signals SG2 and SG2a according to one or more embodiments of the present disclosure.

FIG. 16 schematically illustrates components included in the sensor layer 200 and the sensor driver 200C. Ten first charging electrodes 230-1 and ten second charging electrodes 230-2 are illustrated as a representative example. In addition, to aid understanding, each of the first charging electrodes 230-1 is assigned with the reference numerals of the first charging electrodes STX8, STX9, and STX12 to STX19, and each of the second charging electrodes 230-2 is assigned with the reference numerals of the second charging electrodes STX0 to STX7, STX10, and STX11.

Referring to FIGS. 14, 16, and 17A, signals applied to the first charging electrodes 230-1 and the second charging electrodes 230-2 in each of first, second, third, and fourth time intervals T1, T2, T3, and T4 are illustrated. The signals illustrated in FIG. 17A may be the signals applied to the sensor layer 200 in the searching charge-driving mode. Accordingly, because the position of the pen PN (refer to FIG. 6) is not sensed, the first signal SG1 or the second signal SG2 may be sequentially applied to the entire first charging electrodes 230-1, and the first-first signal SG1a or the second-first signal SG2a may be sequentially applied to the entire second charging electrodes 230-2. That is, the entire area of the sensor layer 200 may be scanned in the searching charge-driving mode.

The electronic device 1000 may include the sensor driver 200C driving the sensor layer 200.

One sensor driver 200C may be electrically connected to the first charging electrodes 230-1 and the second charging electrodes 230-2. The sensor driver 200C may apply the signal to at least a portion of the sixth pads PD6 connected to the first charging electrodes 230-1 to form the first loop LP1, and may apply the signal to at least a portion of the seventh pads PD7 connected to the second charging electrodes 230-2 to form the second loop LP2. However, the present disclosure should not be limited thereto or thereby, and according to one or more embodiments, the sensor driver 200C may apply signals to the third pad PD3 connected to the first loop trace line 230rt1 and to the fourth pad PD4 connected to the second loop trace line 230rt2 to form a loop.

In the first time interval T1, the first signal SG1 may be applied to two first charging electrodes STX18 and STX19, and the second signal SG2 may be applied to two other first charging electrodes STX14 and STX15. In addition, in the first time interval T1, the first-first signal SG1a may be applied to two second charging electrodes STX10 and STX11, and the second-first signal SG2a may be applied to two other second charging electrodes STX6 and STX7. The signals may not be applied to remaining first charging electrodes STX8, STX9, STX12, STX13, STX16, and STX17 or to remaining second charging electrodes STX0 to STX5.

When the pen PN (refer to FIG. 6) is still not sensed, in the second time interval T2, the first signal SG1 may be applied to two first charging electrodes STX17 and STX18, which are shifted by one channel from the two first charging electrodes STX18 and STX19, and the second signal SG2 may be applied to two first charging electrodes STX13 and STX14, which are shifted by one channel from the two first charging electrodes STX14 and STX15.

Because two first charging electrodes STX8 and STX9 are arranged between the two second charging electrodes STX10 and STX11 and the two other second charging electrodes STX6 and STX7, in the second time interval T2, the first-first signal SG1a may be applied to the two second charging electrodes STX6 and STX7, which are shifted by four channels from the two second charging electrodes STX10 and STX11, and the second-first signal SG2a may be applied to two second charging electrodes STX2 and STX3, which are shifted by four channels from the two second charging electrodes STX6 and STX7.

According to the present disclosure, because a portion of the first charging electrodes 230-1 and a portion of the second charging electrodes 230-2 are alternately arranged with each other, even when the pen PN (refer to FIG. 6) approaches a boundary between the first charging electrodes 230-1 and the second charging electrodes 230-2, the pen PN (refer to FIG. 6) may be sensed by the first loop LP1 formed by the first charging electrodes 230-1 or the second loop LP2 formed by the second charging electrodes 230-2. As an example, the pen PN (refer to FIG. 6) may be sensed at the boundary between the first charging electrodes 230-1 and the second charging electrodes 230-2 alternately arranged with the first charging electrodes 230-1.

In addition, according to the present disclosure, because the first loop LP1 and the second loop LP2 are concurrently or substantially simultaneously formed, a time required to scan the entire area of the sensor layer 200 may be reduced by more than half compared to the case where the entire area of the sensor layer 200 is scanned using one loop without dividing the sensor layer 200 into multiple areas. Therefore, the touch performance of the electronic device 1000 (refer to FIG. 2A) may be improved in the charge-driving mode.

Then, when the pen is not sensed continuously, the respective charging electrodes to which the first signal SG1, the second signal SG2, the first-first signal SG1a, and the second-first signal SG2a are applied may be shifted by one or four channels during the third time interval T3 and the fourth time interval T4.

FIG. 17B is a view illustrating first signals SG1 and SG1a and second signals SG2 and SG2a according to one or more embodiments of the present disclosure. In FIG. 17B, details that are the same as those of FIG. 17A will be omitted and descriptions will focus on differences.

Referring to FIGS. 14, 16, and 17B, in a first time interval T1a, the second signal SG2 may be applied to two first charging electrodes STX12 and STX13, and the first signal SG1 may be applied to two other first charging electrodes STX8 and STX9. In addition, in the first time interval T1a, a second-first signal SG2a may be applied to two second charging electrodes STX4 and STX5, and a first-first signal SG1a may be applied to two other second charging electrodes STX0 and STX1. Signals may not be applied to remaining first charging electrodes STX14 to STX19 and remaining second charging electrodes STX2, STX3, STX6, STX7, STX10, and STX11.

When the pen PN (refer to FIG. 6) is still not sensed, because two second charging electrodes STX10 and STX11 are arranged between the two first charging electrodes STX12 and STX13 and the two other first charging electrodes STX8 and STX9, in a second time interval T2a, the second signal SG2 may be applied to two first charging electrodes STX16 and STX17, which are shifted by four channels from the two first charging electrodes STX12 and STX13, and the first signal SG1 may be applied to the two first charging electrodes STX12 and STX13, which are shifted by four channels from the two other first charging electrodes STX8 and STX9. In this case, in FIG. 17B, the shift may occur in a direction opposite to the shift direction in FIG. 17A.

In addition, in the second time interval T2a, the second-first signal SG2a may be applied to two second charging electrodes STX5 and STX6, which are shifted by one channel from the two second charging electrodes STX4 and STX5, and the first-first signal SG1a may be applied to two second charging electrodes STX1 and STX2, which are shifted by one channel from the two other second charging electrodes STX0 and STX1.

Then, when the pen is not sensed continuously, the charging electrodes to which the first signal SG1, the second signal SG2, the first-first signal SG1a, and the second-first signal SG2a are applied during a third time interval T3a and a fourth time interval T4a may be shifted by one or four channels.

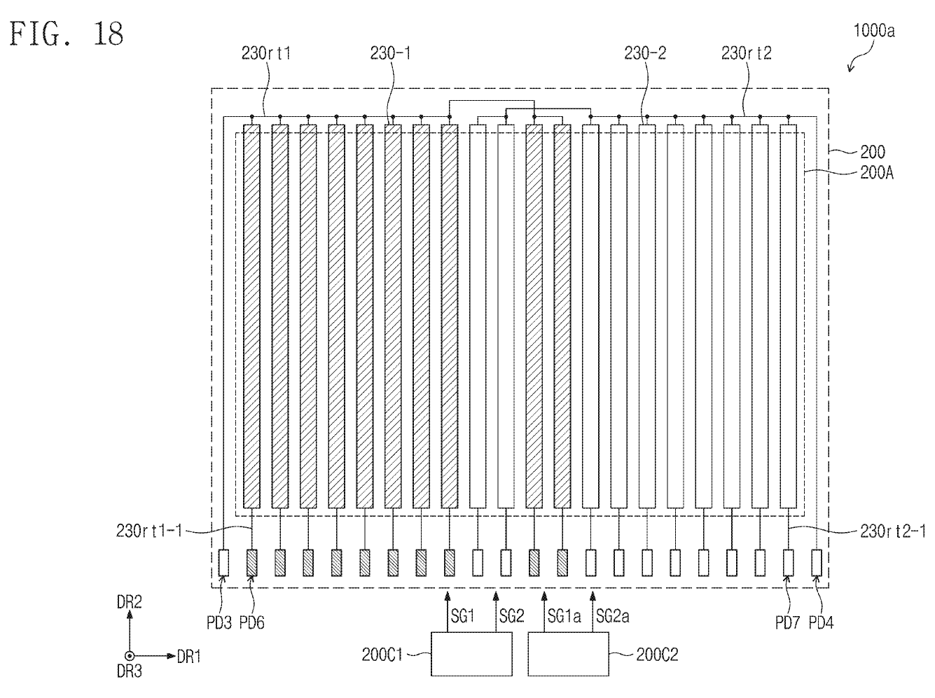

FIG. 18 is a view illustrating a first sensor driver 200C1 and a second sensor driver 200C2 according to one or more embodiments of the present disclosure.

Referring to FIGS. 14 and 18, an electronic device 1000a may include the first sensor driver 200C1 and the second sensor driver 200C2. The first sensor driver 200C1 and the second sensor driver 200C2 may drive a sensor layer 200. The first sensor driver 200C1 and the second sensor driver 200C2 may be referred to as sensor drivers 200C1and 200C2, respectively.

The first sensor driver 200C1 may be electrically connected to first charging electrodes 230-1, and the second sensor driver 200C2 may be electrically connected to second charging electrodes 230-2. The first sensor driver 200C1 may apply a signal to at least a portion of sixth pads PD6 connected to the first charging electrodes 230-1 to form a first loop LP1, and the second sensor driver 200C2 may apply a signal to at least a portion of seventh pads PD7 connected to the second charging electrodes 230-2 to form a second loop LP2, although the present disclosure should not be limited thereto or thereby. According to one or more embodiments, the first sensor driver 200C1 may apply a signal to a third pad PD3 connected to a first loop trace line 230rt1 to form a loop, and the second sensor driver 200C2 may apply a signal to a fourth pad PD4 connected to a second loop trace line 230rt2 to form a loop.

The first sensor driver 200C1 may apply a first signal SG1 and a second signal SG2 to at least the portion of the sixth pads PD6 connected to the first charging electrodes 230-1, and the second sensor driver 200C2 may apply a first-first signal SG1a and a second-first signal SG2a to at least the portion among the seventh pads PD7 connected to the second charging electrodes 230-2.

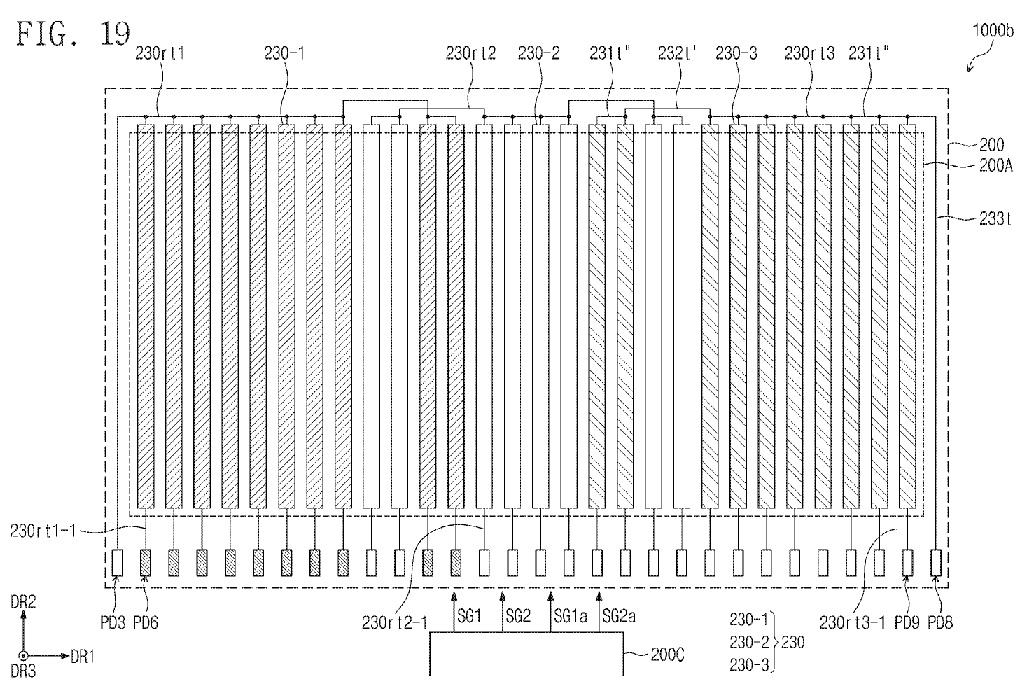

FIG. 19 is a view illustrating an electronic device 1000b including a sensor layer 200 according to one or more embodiments of the present disclosure. In FIG. 19, details that are the same as those of FIG. 14 will be omitted and descriptions will focus on differences.

Referring to FIGS. 14 and 19, third electrodes 230 may further include a plurality of third charging electrodes 230-3. The third charging electrodes 230-3 may be arranged in the first direction DR1.

At least one third charging electrode 230-3 among the third charging electrodes 230-3 may be arranged between at least one second charging electrode 230-2 among the second charging electrode 230-2 and the other (e.g., a remainder of) second charging electrodes 230-2 among the second charging electrode 230-2. As an example, referring to FIG. 19, two third charging electrodes 230-3 among the third charging electrodes 230-3 may be arranged between two second charging electrodes 230-2 among second charging electrodes 230-2 and remaining six second charging electrodes 230-2 among second charging electrodes 230-2. However, the present disclosure should not be limited thereto or thereby, and the arrangement of the first charging electrodes 230-1, the second charging electrodes 230-2, and the third charging electrodes 230-3 may be modified in various ways.

According to the present disclosure, a portion of the third charging electrodes 230-3 and a portion of the second charging electrodes 230-2 may be arranged to cross with each other. Accordingly, a current loop that generates a magnetic field required to charge a pen may be formed in an area where the third charging electrodes 230-3 of the sensor layer 200 are located, an area where the second charging electrodes 230-2 are located, and areas between the portion of the third charging electrodes 230-3 and the portion of the second charging electrodes 230-2. In addition, a current loop using the first charging electrodes 230-1 and a current loop using the second charging electrodes 230-2 may be concurrently or substantially simultaneously formed. Accordingly, the charging performance of the pen PN (refer to FIG. 6) may be improved. As an example, the charging speed of the pen PN (refer to FIG. 6) and the charge rate of the pen PN (refer to FIG. 6) may be improved, and thus, linearity and accuracy for inputs generated by the pen PN (refer to FIG. 6) may be improved. That is, the touch performance of the electronic device 1000b may be improved.

The sensor layer 200 may further include a third loop trace line 230rt3, an eighth pad PD8 connected to one end of the third loop trace line 230rt3, third-first loop trace lines 230rt3-1, and ninth pads PD9 connected to the third-first loop trace lines 230rt3-1 in a one-to-one correspondence, which are arranged in a peripheral area 200NA.

The third loop trace line 230rt3 may be electrically connected to the third charging electrodes 230-3. That is, the third loop trace line 230rt3 may be electrically connected to all the third charging electrodes 230-3.

The third loop trace line 230rt3 may include a plurality of first-second portions 231t’’ extending along the first direction DR1 and electrically connected to the third charging electrodes 230-3, a second-second portion 232t’’ electrically connecting the first-second portions 231t’’ and arranged between the first-second portions 231t’’, and a third-second portion 233t’’ extending from one end of the first-second portions 231t’’ along the second direction DR2.

A second loop trace line 230rt2 and the third loop trace line 230rt3 may be insulated from each other while crossing with each other. As an example, a second-first portion 232t’ of the second loop trace line 230rt2 and the second-second portion 232t’’ of the third loop trace line 230rt3 may be insulated from each other while crossing with each other. Accordingly, the second charging electrodes 230-2 electrically connected to the second loop trace line 230rt2 may be electrically insulated from the third charging electrodes 230-3 electrically connected to the third loop trace line 230rt3.

In the present disclosure, the case where the sensor layer is divided into two areas or three areas is described as a representative example, but the present disclosure should not be limited thereto or thereby. When the size of a sensor increases, the sensor layer 200 may be divided into N areas, and in this case, the N is an integer greater than 3.

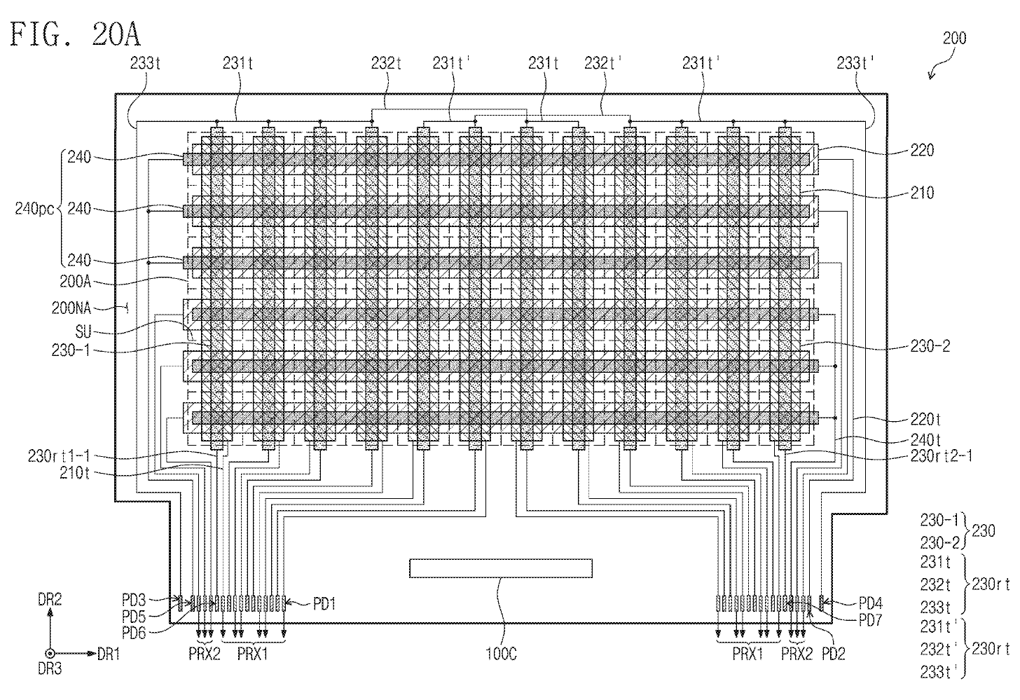

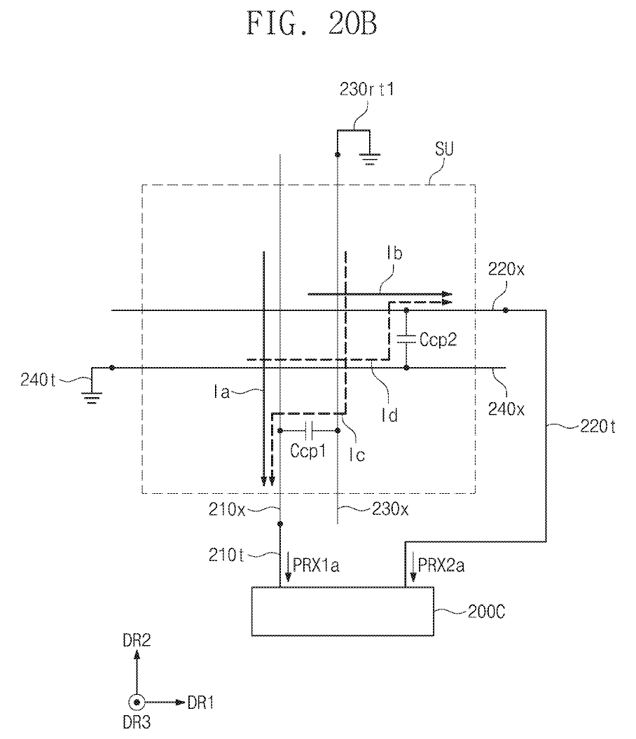

FIG. 20A is a view illustrating a second mode according to one or more embodiments of the present disclosure, and FIG. 20B is a view illustrating the second mode with respect to one sensing unit according to one or more embodiments of the present disclosure.

Referring to FIGS. 20A and 20B, the second mode may include a charge-driving mode and a pen-sensing-driving mode. FIGS. 20A and 20B are views illustrating the pen-sensing-driving mode.

Referring to FIG. 20A, in the pen-sensing-driving mode, first reception signals PRX1 may be output from first electrodes 210, and second reception signals PRX2 may be output from second electrodes 220. FIG. 20B illustrates one sensing unit SU through which first, second, third, and fourth induced currents Ia, Ib, Ic, and Id generated by a pen flow.

Referring to FIGS. 20A and 20B, a routing direction of one electrode and a routing direction of another electrode of a sensor layer 200, which overlaps the one electrode, may be different from each other. As an example, a routing direction of a first electrode 210x and a routing direction of a third electrode 230x may be different from each other. In addition, a routing direction of a second electrode 220x and a routing direction of a fourth electrode 240x may be different from each other. As an example, as shown in FIG. 20B, the first electrode 210x and a first trace line 210t may be connected to each other at a lower side of the sensing unit SU, and the third electrode 230x and a first loop trace line 230rt1 may be connected to each other at an upper side of the sensing unit SU. The second electrode 220x and a second trace line 220t may be connected to each other at a right side of the sensing unit SU, and the fourth electrode 240x and an auxiliary trace line 240t may be connected to each other at a left side of the sensing unit SU.

An RLC resonant circuit of a pen PN may emit a magnetic field at its resonant frequency while discharging electric charge charged therein. Due to the magnetic field provided from the pen PN, the first induced current Ia may be generated in the first electrode 210x, and the second induced current Ib may be generated in the second electrode 220x. In addition, the third induced current Ic may be generated in the third electrode 230x, and the fourth induced current Id may be generated in the fourth electrode 240x.

A first coupling capacitor Ccp1 may be formed between the third electrode 230x and the first electrode 210x, and a second coupling capacitor Ccp2 may be formed between the fourth electrode 240x and the second electrode 220x. The third induced current Ic may be supplied to the first electrode 210x via the first coupling capacitor Ccp1, and the fourth induced current Id may be supplied to the second electrode 220x via the second coupling capacitor Ccp2.

A sensor driver 200C may receive a first reception signal PRX1a from the first electrode 210x based on the first induced current Ia and the third induced current Ic, and may receive a second reception signal PRX2a from the second electrode 220x based on the second induced current Ib and the fourth induced current Id. The sensor driver 200C may detect input coordinates of the pen PN based on the first reception signal PRX1a and the second reception signal PRX2a.

The sensor driver 200C may receive the first reception signal PRX1a from the first electrode 210x, and may receive the second reception signal PRX2a from the second electrode 220x. In this case, one end of the third electrode 230x and one end of the fourth electrode 240x may all be floated. Therefore, the compensation for the sensing signal may increase by the coupling between the first electrode 210x and the third electrode 230x and the coupling between the second electrode 220x and the fourth electrode 240x.

In addition, the other end of the third electrode 230x and the other end of the fourth electrode 240x may be grounded or floated. Accordingly, due to the coupling between the first electrode 210x and the third electrode 230x and the coupling between the second electrode 220x and the fourth electrode 240x, the third induced current Ic and the fourth induced current Id may be sufficiently supplied to the first electrode 210x and the second electrode 220x.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present present disclosure shall be determined according to the attached claims.

What is claimed is:

1. An electronic device comprising:
a display layer comprising a display area for displaying an image, and a non-display area adjacent to the display area; and
a sensor layer above the display layer for sensing an external input, and comprising:
first electrodes arranged in a first direction;
second electrodes arranged in a second direction crossing the first direction;
first charging electrodes arranged in the first direction;
second charging electrodes arranged in the first direction;
a first loop trace line electrically connected to the first charging electrodes; and
a second loop trace line electrically connected to the second charging electrodes,
wherein at least one of the first charging electrodes is between at least one of the second charging electrodes and a remainder of the second charging electrodes.

2. The electronic device of claim 1, further comprising a sensor driver configured to drive the sensor layer and electrically connected to the first charging electrodes and to the second charging electrodes.

3. The electronic device of claim 1, further comprising a first sensor driver electrically connected to the first charging electrodes, and a second sensor driver electrically connected to the second charging electrodes, which are configured to drive the sensor layer.

4. The electronic device of claim 1, wherein the first charging electrodes are electrically insulated from the second charging electrodes.

5. The electronic device of claim 1, further comprising a sensor driver configured to drive the sensor layer,
wherein the sensor layer is configured to selectively operate in a first mode for sensing a touch input, or in a second mode for sensing a pen input and comprising a charge-driving mode, and
wherein the sensor driver is configured to apply a signal to at least a portion of the first charging electrodes to form a first loop in the charge-driving mode, and is configured to apply a signal to at least a portion of the second charging electrodes to form a second loop in the charge-driving mode.

6. The electronic device of claim 5, wherein the sensor driver is configured to drive the first charging electrodes and the second charging electrodes substantially simultaneously in the charge-driving mode.

7. The electronic device of claim 1, wherein the first loop trace line is insulated from the second loop trace line while crossing with the second loop trace line.

8. The electronic device of claim 1, wherein the sensor layer further comprises:
third charging electrodes arranged in the first direction; and
a third loop trace line electrically connected to the third charging electrodes,
wherein at least one of the third charging electrodes is arranged between at least one of the second charging electrodes and a remainder of the second charging electrodes.

9. The electronic device of claim 8, wherein the first loop trace line is insulated from the second loop trace line while crossing with the second loop trace line, and
wherein the second loop trace line is insulated from the third loop trace line while crossing with the third loop trace line.

10. The electronic device of claim 1, wherein the sensor layer further comprises:
first trace lines electrically connected to the first electrodes in a one-to-one correspondence; and
second trace lines electrically connected to the second electrodes in a one-to-one correspondence.

11. The electronic device of claim 10, wherein the sensor layer further comprises:
auxiliary electrodes arranged in the second direction; and
an auxiliary trace line electrically connected to the auxiliary electrodes.

12. An electronic device comprising:
a display layer comprising a display area for displaying an image, and a non-display area adjacent to the display area;
a display driver for driving the display layer;
a sensor driver;
a processor for controlling an operation of the display driver and the sensor driver; and
a sensor layer above the display layer, configured to be driven by the sensor driver, configured to selectively operate in a first mode for sensing a touch input, or a second mode for sensing a pen input and comprising a charge-driving mode, and comprising:
first electrodes arranged in a first direction;
second electrodes arranged in a second direction crossing the first direction;
first charging electrodes arranged in the first direction;
second charging electrodes arranged in the first direction and electrically insulated from the first charging electrodes;
a first loop trace line electrically connected to the first charging electrodes; and
a second loop trace line electrically connected to the second charging electrodes, and
wherein the sensor driver is configured to apply a signal to at least a portion of the first charging electrodes to form a first loop in the charge-driving mode, and is configured to apply a signal to at least a portion of the second charging electrodes to form a second loop in the charge-driving mode.

13. The electronic device of claim 12, wherein the sensor driver is electrically connected to the first charging electrodes and to the second charging electrodes.

14. The electronic device of claim 12, wherein the sensor driver further comprises a first sensor driver electrically connected to the first charging electrodes, and a second sensor driver electrically connected to the second charging electrodes.

15. The electronic device of claim 12, wherein the sensor driver is configured to substantially simultaneously drive the first charging electrodes and the second charging electrodes in the charge-driving mode.

16. The electronic device of claim 12, wherein the sensor driver is configured to drive either the first charging electrodes or the second charging electrodes in the charge-driving mode.

17. The electronic device of claim 12, wherein the first loop trace line is insulated from the second loop trace line while crossing with the second loop trace line.

18. The electronic device of claim 12, wherein at least one of the first charging electrodes is between at least one of the second charging electrodes and a remainder of the second charging electrodes.

19. The electronic device of claim 12, wherein the sensor layer further comprises:
third charging electrodes arranged in the first direction; and
a third loop trace line electrically connected to the third charging electrodes, and
wherein at least one of the third charging electrodes is arranged between at least one of the second charging electrodes and a remainder of the second charging electrodes.

20. The electronic device of claim 19, wherein the first loop trace line is insulated from the second loop trace line while crossing with the second loop trace line, and
wherein the second loop trace line is insulated from the third loop trace line while crossing with the third loop trace line.
